(19) United States
(12) Patent Application Publication
(10) Pub. No.: US 2004/0238211 A1
(43) Pub. Date: Dec. 2, 2004

(54) Circuit board, circuit board mounting method, and electronic device using the circuit board

(76) Inventors: Yuki Momokawa, Tokyo (JP); Eiichi Kono, Tokyo (JP); Masaru Saitou, Tokyo (JP); Kazuhiko Tanabe, Tokyo (JP)

Correspondence Address: SUGHRUE MION, PLLC, 2100 PENNSYLVANIA AVENUE, N.W., SUITE 800, WASHINGTON, DC, 20037, US

(21) Appl. No.: 10/474,427

(22) PCT Filed: Apr. 9, 2002
(86) PCT No.: PCT/JP02/03526

(30) Foreign Application Priority Data
Apr. 10, 2001 (JP) 2001-110886
Jun. 5, 2001 (JP) 2001-169576

(51) Int. Cl. H05K 1/11; H05K 3/34

(52) U.S. Cl. 174/260; 29/840; 174/264; 174/263

(57) ABSTRACT

A through hole 2 in a circuit board 1 and to be joined to a lead 5 in a surface mounting component 6 is prepared from a material such as nickel, and palladium having a thermal conductivity equal to or less than 100 W/m.K, the circuit board 1 involving a alloy layer composed of at least a member selected from elements of solder 8, a pad 7, and the lead 5 in a solder joined site of the lead 5 and the pad 7, whereby a quantity of heat transmitted to the joined site via the through hole 2 is reduced at the time when wave-soldering is applied to the back of the circuit board 1 after the surface mounting component 6 was mounted, so that the joined site is maintained at a temperature equal to or less than a melting point of the alloy layer, and hence, exfoliation in an interface of the joined site is prevented, and reliability in the joint of the lead 5 and the pad 7 is elevated.

### TECHNICAL FIELD

The present invention relates to a circuit board, and electronic equipment using the circuit board, and more particularly to a circuit board on which a surface mounting type electronic component and an inserting type electronic component are mounted in a hybrid manner using lead-free solder, and electronic equipment using the circuit board.

### BACKGROUND FIELD

Most of mount boards have been heretofore ones of a type wherein a surface mounting type electronic component and an inserting type electronic component had been mounted on a circuit board. A structure and a process for the production of a mount board to which a conventional circuit board has been applied will be described in detail by referring to FIGS. 1 through 4 wherein FIG. 1 is a top view showing a state where a surface mounting component 6 has been mounted on a circuit board 1 on which through holes have been defined, FIG. 2 is an enlarged plan view of a part C of FIG. 1, FIG. 3 is a sectional view taken along the line C-C′ of FIG. 1, and FIG. 4 is a sectional view taken along the line C-C′ of FIG. 1 wherein a multi-layered interconnection board is used.

As shown in FIGS. 1 through 4, a copper-filled laminate substrate is prepared by subjecting a copper foil to pressure and heat treatment with respect to an insulating sheet obtained by infiltrating epoxy resin, phenolic resin or the like into a paper base material, a glass base material, a polyester fiber base material or the like, an open hole is defined at a desired position of the copper-filled laminate substrate, a catalyst is applied to a side surface of the open hole, then, a first plating is conducted in accordance with an electroless copper plating method, a conductor is formed thereon in accordance with electrolytic copper plating method, and the conductor is bonded to a copper film on the surface of the copper-filled laminate substrate to form a through hole 2. Thereafter, when a conductive film composed of copper residing on the surface of the copper-filled laminate substrate is etched, a land 3, an interconnection 4, and a pad 7 are formed. Finally, a solder resist 10 is printed and applied in such a manner that solder 8, 9 is not applied to an area other than the land 3 to which should be soldered, and then, the solder resist 10 applied is exposed to light, whereby a circuit board 1 is prepared.

The solder 8 is printed and applied to the pad 7 of the circuit board 1, on which a surface mounting component 6 is loaded, and the solder 8 is heated and molten in a reflow oven, whereby the pad 7 is joined to a lead 5 of the surface mounting component 6 on the circuit board 1. Then, in order to mount an inserting type electronic component, a flux is applied to the back of the circuit board 1, and then, soldering is conducted in a solder bath. As a result, a through hole into which an inserting type electronic component is to be inserted as well as a part or the whole of the through hole 2 to be joined to the surface mounting component 6 are filled with the solder 9.

In this respect, however, environmental pollution derived from lead has become a subject of discussion in recent years, so that changeover into use of lead-free solder containing no lead is requested. Such lead-free solder consists of tin as the major component other than silver, copper, zinc, bismuth, indium, antimony, nickel, germanium and the like. Typical lead-free solder of tin-silver based solder exhibits about 220° C. melting temperature. Tin in the solder, copper of the pad 7 in the circuit board 1, and copper or nickel of the lead 5 in the surface mounting component 6 are reacted with each other to form a alloy layer, whereby the pad 7 in the circuit board 1 is joined to the lead 5 of the surface mounting component 6.

In this case, when lead is contained in an electroplate or a solder coat in the pad 7 of the circuit board 1, the lead segregates between the above-described alloy layer and the solder to form a tin-silver-lead ternary alloy layer. A melting temperature of 174° C. in a eutectic composition (1.3 at % of Ag, 24.0 at % of Pb, and the remainder of Sn) of the ternary alloy is lower than that of tin-silver based solder, so that an appearance of such condition is the one wherein a difference between liquidus curve and solidus curve is remarkable.

Incidentally, a solid interconnection existing in the through hole 2, the solder 9, the land 3, and an inside wiring 11 for the circuit board and the multi-layered interconnection board is composed of copper in a conventional circuit board 1.

Under the circumstances, when the wave-soldering as mentioned above is implemented, there is a case where a temperature of the solder 8 exceeds melting temperature of 174° C. of the ternary alloy due to heat of the through hole 2 and the solder 9 transmitted through the interconnection 4 and the inner layer wiring 11 as well as heat transmitted from the solder being in contact with the solder resist 10 through the inner layer wiring 11 and the insulating layer 12 because of a high thermal conductivity of copper (386 W/m.K), so that only the ternary alloy layer melts despite the fact that all of the solder 8 does not melt.

In this case, when an external force such as a camber is applied to the circuit board 1 or the surface mounting component 6, exfoliation appears in a molten site of the ternary alloy layer, i.e., the site between the lead 5 of the surface mounting component 6 and the solder, or the site between the pad 7 of the circuit board 1 and the solder 8, so that a connection between the pad 7 of the circuit board 1 and the lead 5 of the surface mounting component 6 cannot be maintained. Furthermore, even in the case where only a part of the molten site is exfoliated, a joined area decreases so that there arises a problem of significant decrease in reliability in electronic equipment,

### DISCLOSURE OF THE INVENTION

The present invention has been made to solve the above-described problems. Accordingly, a major object of the present invention is to provide a highly reliable circuit board and a method for mounting the circuit board by which no exfoliation appears in a joined site in a terminal of a surface mounting component that has been mounted by the use of lead-free solder.

Moreover, a further object of the present invention is to provide highly reliable electronic equipment to which the above-described circuit board or multi-layered interconnection board has been applied.

In order to achieve the above-described objects, a circuit board for mounting a surface mounting component according to the present invention comprises a temperature of a joined site of a terminal of the surface mounting component and an electrode pad of the circuit board being made to be not equal to or more than a melting temperature of a alloy layer formed in the joined site.

Furthermore, a circuit board according to the present invention involving a alloy layer made of at least an element of solder, a terminal of a surface mounting component to be mounted on a surface of the circuit board, an electrode pad of the circuit board in either an interface residing in between the terminal and the solder, or an interface residing in between the electrode pad and the solder in a joined site of the terminal and the electrode pad with the solder, comprises a means for suppressing conduction of heat being disposed on a thermal conduction path extending from the back of the circuit board on the side opposite to the side on which the surface mounting component has been mounted to the electrode pad; and a temperature of the joined site being maintained by the means at a temperature equal to or less than a melting temperature of the alloy layer.

In a circuit board of the present invention, it is preferred that the alloy layer includes a ternary alloy consisting of tin and silver contained in the solder, and lead contained in the terminal or the electrode pad.

In a circuit board of the present invention, at least one of a through hole joined to the electrode pad and a land formed around a surrounding of the through hole may be prepared from a material having a thermal conductivity equal to or less than a predetermined value.

In a circuit board of the present invention, the interior of a through hole to be joined to the electrode pad may be filled with a material having a thermal conductivity equal to or less than a predetermined value.

In a circuit board of the present invention at least a part of an interconnection for connecting a through hole to be joined to the electrode pad with the same may be prepared from a material having a thermal conductivity equal to or less than a predetermined value.

In a circuit board of the present invention, it is preferred that the above-described predetermined thermal conductivity is equal to or less than 100 W/m.K, and further, a material having the above-described predetermined thermal conductivity is nickel or palladium.

In a circuit board of the present invention, an interconnection for connecting a through hole to be joined to the electrode pad with the same may be formed so as to have a length equal to or longer than a predetermined value, and the length of the interconnection is preferably 10 mm or longer.

In a circuit board of the present invention, at least a part of an interconnection for connecting a through hole to be joined to the electrode pad with same may be formed so as to have a predetermined sectional area or less, and the predetermined sectional area is preferably 0.0035 mm² or less.

In a circuit board of the present invention, the circuit board may be composed of a multi-layered interconnection board and may involve an area on which formation of a solid pattern is forbidden in the whole or a part of an inner layer of a region including immediately below a position in which the surface mounting component has been mounted.

A surface mounting component to be mounted on a circuit board according to the present invention comprises at least a part of a terminal in the surface mounting component having a laminated structure composed of a plurality of materials each exhibiting a different coefficient of thermal expansion; a layer prepared from a material having a small coefficient of thermal expansion being disposed on the side of the circuit board; and the terminal being deformed in a direction along which the terminal pushes the circuit board due to temperature rise in case of wave-soldering the back of the circuit board.

In a surface mounting component of the present invention, a layer prepared from a material having a different coefficient of thermal conductivity from that of a major component of the terminal may be disposed on a bent portion of the terminal.

A surface mounting component to be mounted on a circuit board according to the present invention comprises at least a surface of a terminal in the surface mounting component being prepared from a predetermined material having a higher coefficient of thermal conductivity than that of Cu, whereby transfer of heat flowing into a joined site of the terminal is promoted with respect to a main body of the surface mounting component in case of wave-soldering the surface mounting component on the back of the circuit board.

In a surface mounting component, the above-described predetermined material may contain Ag.

Electronic equipment according to the present invention comprises at least either of the above-described circuit board, or the above-described surface mounting component.

A method for mounting a circuit board wherein wave-soldering is applied on the back side of the circuit board opposite to a surface on which a surface mounting component is to be mounted after mounting the same according to the present invention comprises cooling at least a vicinity of a joined site of the surface mounting component and the circuit board in case of the wave-soldering step, whereby a temperature of the joined site is maintained at a melting temperature or less of a alloy layer formed in the joined site.

A method for mounting a circuit board wherein wave-soldering is applied on the back side of the circuit board opposite to a surface on which a surface mounting component is to be mounted after mounting the same according to the present invention comprises disposing a heat sink member in a region including at least the upper surface of the surface mounting component in case of the wave-soldering step, whereby a temperature of the joined site of the surface mounting component and the circuit board is maintained at a melting temperature or less of a alloy layer formed in the joined site.

In a method for mounting a circuit board of the present invention, the heat sink member may be made to be in contact with a terminal of the surface mounting component or solder in the joined site.

A method for mounting a circuit board wherein wave-soldering is applied on the back side of the circuit board opposite to a surface on which a surface mounting component is to be mounted after mounting the same according to the present invention comprises warming at least a vicinity of a joined site of the surface mounting component and the circuit board in case of the wave-soldering step, whereby the whole solder in the joined site is molten.

A method for mounting a circuit board wherein wave-soldering is applied on the back side of the circuit board opposite to a surface on which a surface mounting component is to be mounted after mounting the same according to the present invention comprises disposing a material for suppressing heat transmission in a region including at least one of a through hole, a land, and an interconnection, which are to be connected with the surface mounting component, or an area situated immediately below the surface mounting component in case of the wave-soldering step.

In a method for mounting a circuit board of the present invention the above-described material for suppressing heat transmission may be a heat-insulating tape or resin.

As described above, according to the above-described constitution of the present invention, a temperature of a terminal joined site in a surface mounting component is suppressed at a melting temperature or less of a alloy layer formed in the joined site in the case when wave-soldering is applied to the back of a circuit board after the surface mounting component was mounted thereon, or the whole solder is molten or the terminal is bent with respect to the side of the circuit board in the case where the alloy layer was molten. As a result, it may be achieved to elevate reliability in joint of the terminal in the surface mounting component and an electrode pad in the circuit board.

### BRIEF DESCRIPTION OF THE DRAWINGS

FIG. 1 is a top view showing a conventional circuit board;

FIG. 2 is an enlarged top view showing the conventional circuit board:

FIG. 3 is a sectional view showing the conventional circuit board;

FIG. 4 is a sectional view showing a conventional multi-layered interconnection board;

FIG. 5 is a sectional view showing a structure of a circuit board according to a first example of the present invention;

FIG. 6 is a sectional view showing a structure of a circuit board according to a second example of the present invention;

FIG. 7 is a sectional view showing a structure of a circuit board according to a third example of the present invention;

FIG. 8 is a sectional view showing a structure of a circuit board according to a fourth example of the present invention;

FIG. 9 is a sectional view showing a structure of a circuit board according to a fifth example of the present invention;

FIG. 10 is a table for explaining advantageous effects of the present invention wherein experimental data of the prior art are compared with that of the present invention;

FIG. 11 is a photograph showing an appearance of an unsuccessful site, in section, of a conventional product based on the experimental data of FIG, 10;

FIG. 12 is a photograph showing an appearance of a successful site, in section, of a product according to the first example of the present invention based on the experimental data of FIG. 10;

FIG. 13 is a top view showing a structure of a circuit board according to a sixth example of the present invention;

FIG. 14 is a top view showing a structure of a circuit board according to a seventh example of the present invention;

FIG. 15 is an enlarged top view showing a structure of a circuit board according to an eighth example of the present invention;

FIG. 16 is an enlarged top view showing a structure of a circuit board according to a ninth example of the present invention:

FIG. 17 is an enlarged top view showing a structure of a circuit board according to a tenth example of the present invention;

FIG. 18 is an enlarged top view showing a structure of a circuit board according to an eleventh example of the present invention;

FIG. 19 is an enlarged top view showing a structure of a circuit board according to a twelfth example of the present invention;

FIG. 20 is an enlarged top view showing a structure of a circuit board according to a thirteenth example of the present invention;

FIG. 21 is an enlarged top view showing a structure of a circuit board according to a fourteenth example of the present invention;

FIG. 22 is an enlarged top view showing a structure of a circuit board according to a fifteenth example of the present invention;

FIG. 23 is an enlarged top view showing a structure of a circuit board according to a sixteenth example of the present invention;

FIG. 24 is an enlarged top view showing a structure of a circuit board according to a seventeenth example of the present invention;

FIG. 25 is an enlarged top view showing a structure of a circuit board according to an eighteenth example of the present invention;

FIGS. 26(a) and 26(b) are comparative photographs wherein FIG. 26(a) shows an example of interconnection of the prior art, and FIG. 26(b) shows an example of interconnection according to the present invention;

FIG. 27 is an enlarged top view showing a structure of a circuit board according to a nineteenth example of the present invention;

FIG. 28 is a sectional view showing a structure of a circuit board according to the nineteenth example of the present invention;

FIG. 29 is a sectional view showing a structure of a circuit board according to a twentieth example of the present invention;

FIG. 30 is a sectional view showing a structure of a circuit board according to a twenty-first example of the present invention;

FIG. 31 is a sectional view showing a condition of a wave-soldering technology according to a twenty-second example of the present invention;

FIG. 32 is a sectional view showing a structure of a circuit board according to a twenty-third example of the present invention;

FIG. 33 is a sectional view showing a structure of a circuit board according to the twenty-third example of the present invention;

FIG. 34 is a sectional view showing a structure of a circuit board according to the twenty-third example of the present invention;

FIG. 35 is a sectional view showing a condition of a wave-soldering technology according to a twenty-fourth example of the present invention;

FIG. 36 is a sectional view showing a structure of a circuit board according to a twenty-fifth example of the present invention;

FIG. 37 is a sectional view showing a structure of a circuit board according to a twenty-sixth example of the present invention;

FIG. 38 is a sectional view showing a structure of a circuit board according to the twenty-seventh example of the present invention;

FIG. 39 is a sectional view showing a structure of a circuit board according to the twenty-seventh example of the present invention;

FIG. 40 is a sectional view showing a structure of a circuit board according to the twenty-seventh example of the present invention; and

FIG. 41 is a graphical representation for explaining advantageous effects of the present invention.

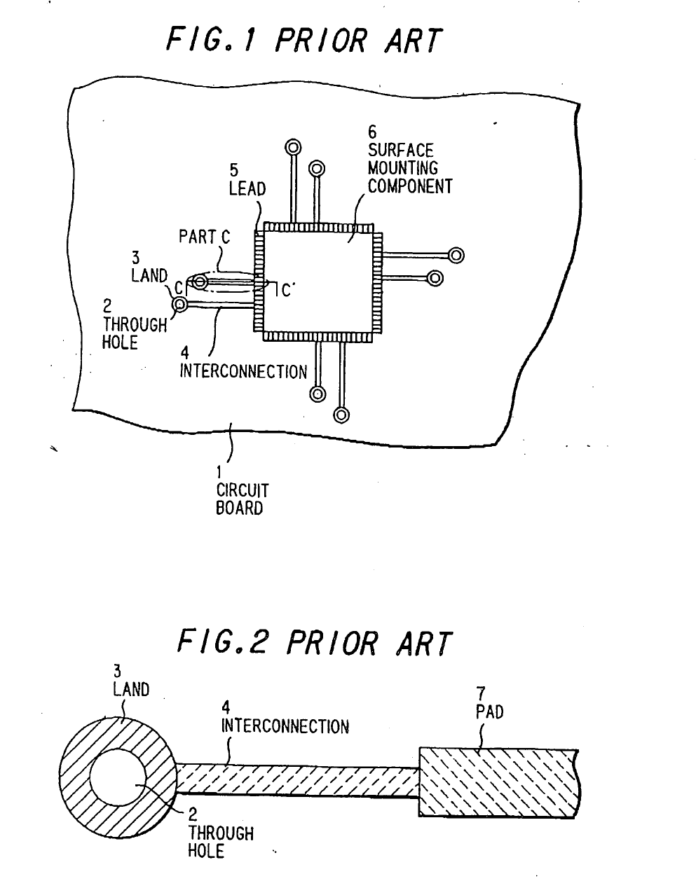

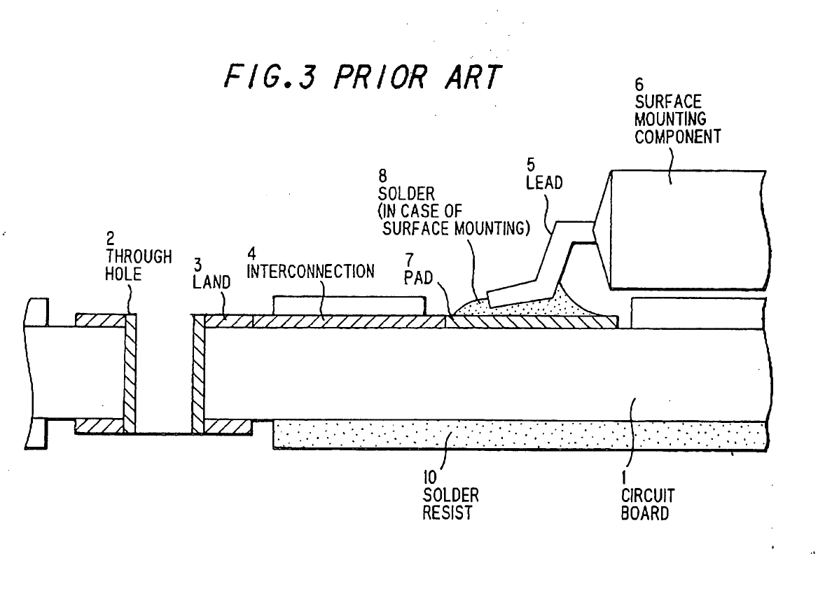

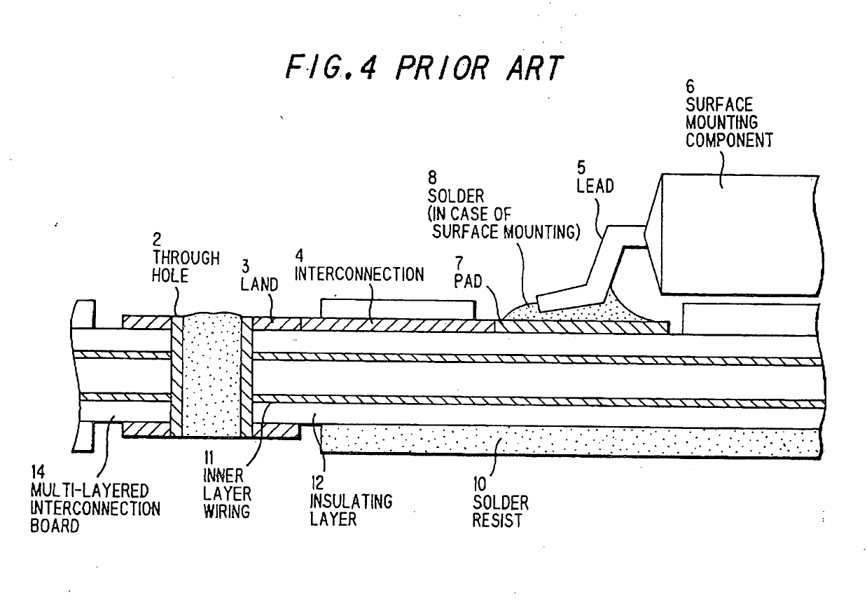

### THE BEST MODE FOR EXECUTING THE INVENTION

In a preferred embodiment according to the present invention, a circuit board according to the present invention wherein a surface mounting component is mounted on the surface side thereof, while wave-soldering is applied to the back side thereof, comprises a alloy layer containing elements composing solder and a pad or a lead being formed on a solder joined site of the lead and the pad in the surface mounting component; and either a means for suppressing temperature rise of the alloy layer equal to or lower than a melting temperature thereof in case of soldering the back of the circuit board after mounting the surface mounting component, or a means for suppressing exfoliation in the alloy layer in case of melting the alloy layer. Thus, the circuit board according to the present invention can improve reliability in joint between the lead and the pad.

In the following, preferred embodiments of the present invention will be described in detail in conjunction with the accompanying drawings.

Before the description, it is to be noted that a process for the production of circuit boards is the same in both the present invention and the prior art, so that the explanation therefor is omitted herein.

[Embodiment 1]

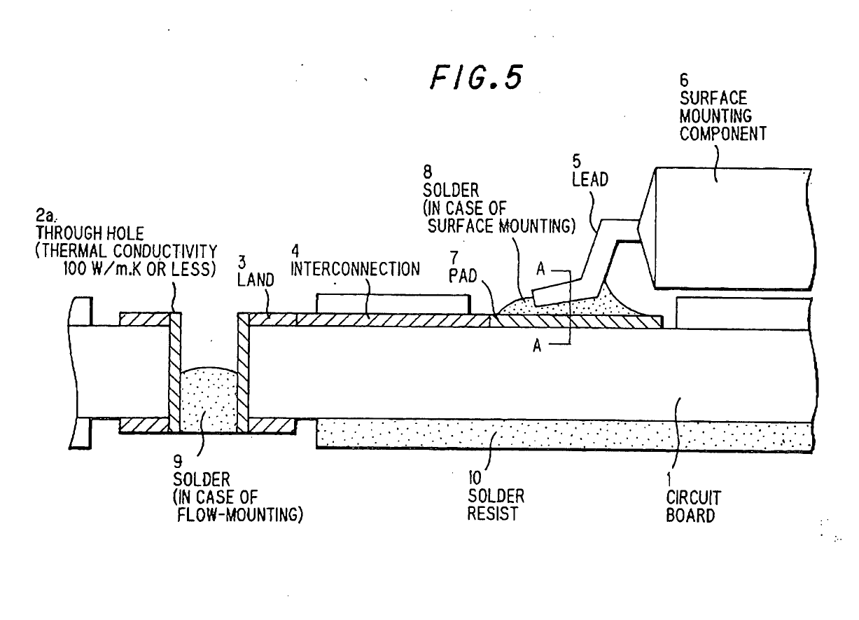

As shown in FIGS. 5 through 12, a circuit board according to the first embodiment of the present invention is constituted in such that at least one member selected from an inner wall of a through hole to be defined in the circuit board, a land of the through hole, and a material to be filled inside the through hole is composed of the one having a thermal conductivity equal to or lower than a predetermined value, whereby conduction of heat transmitted via the through hole in case of wave-soldering is suppressed. A material having a low thermal conductivity is disposed on a heat conductive path, so that heat flows into solder in a lead joined site in a surface mounting component through an interconnection thereby preventing melting of a alloy layer formed in the lead joined site.

In this case, it is the better that a material of the inner wall of the through hole, that of the land, or that to be filled inside the through hole has the lower thermal conductivity. On the other hand, it is also required to select a metal having a good electrical conductivity. When these conditions are totally taken into consideration, a preferred material is nickel, palladium, or the like. Based on the fact that nickel has a thermal conductivity of 58 to 90 W/m.K and palladium has 76 W/m.K thermal conductivity, when a thermal conductivity is maintained at 100 W/m.K or less, exfoliation and the like due to fusion of the alloy layer can be suppressed. A specific constitution thereof will be described in detail in first through fifth examples described hereunder.

[Embodiment 2]

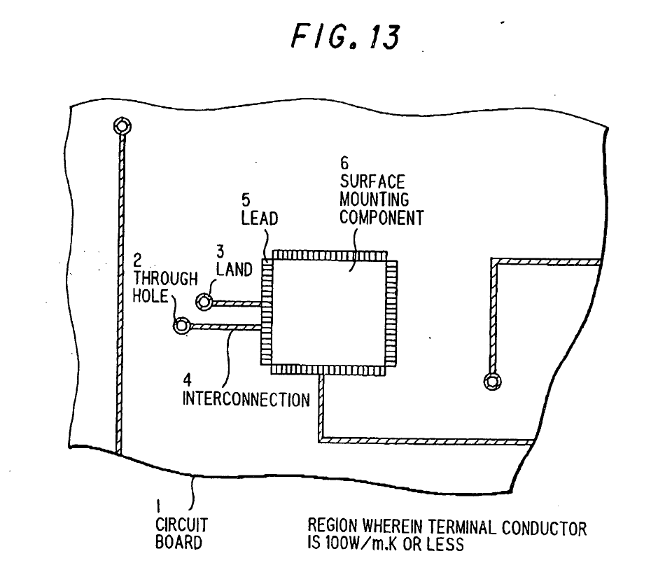

As shown in FIGS. 13 through 26, a circuit board according to the second embodiment of the present invention is constituted in such that at least a part of an interconnection between a through hole defined in the circuit board and a pad to which a lead of a surface mounting component is to be joined is composed of a material having a thermal conductivity equal to or lower than a predetermined value, or an interconnection length is made to be a value equal to or longer than a predetermined value, or further an sectional area of the interconnection is made to be equal to or lower than a predetermined value. Thus, thermal conduction transmitted via the through hole at the time of wave-soldering is suppressed, so that heat flowing into solder in a lead joined site of the surface mounting component transmitted through the interconnection is suppressed, whereby fusion of a alloy layer formed in the lead joined site is prevented.

It is preferred herein that a thermal conductivity of the interconnection is a value being equal to or lower than 100 W/m.K as in the case of the first embodiment.

Furthermore, it has been confirmed by experiments conducted by the present inventors that when an interconnection length is made to be ten (10) mm or longer, or a sectional area of the interconnection is made to be 0.0035 mm² or less, any exfoliation and the like does not appear. A specific constitution thereof will be described in detail in sixth through eighth examples mentioned hereunder.

[Embodiment 3]

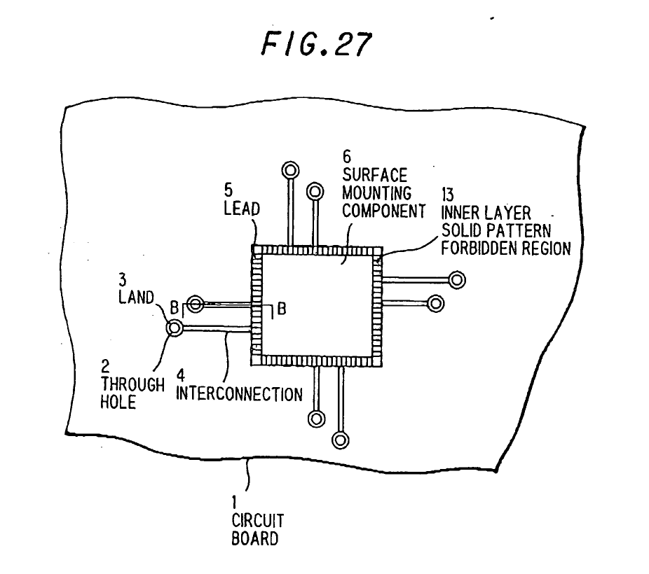

As shown in FIGS. 27 through 30, a circuit board according to the third embodiment of the present invention is constituted in such that an area wherein no inner layer solid pattern is formed in at least a part of a region where a surface mounting component of a multi-layered interconnection board is to be mounted is provided, whereby thermal conduction transmitted by crossing over the multi-layered interconnection board in case of wave-soldering is suppressed, so that heat flowing into solder in a lead joined site of a surface mounting component transmitted through the interior of the multi-layered interconnection board is suppressed, whereby fusion of a alloy layer formed on the lead joined site is prevented.

A specific constitution thereof will be described in detail in nineteenth through twenty-first examples mentioned hereunder.

[Embodiment 4]

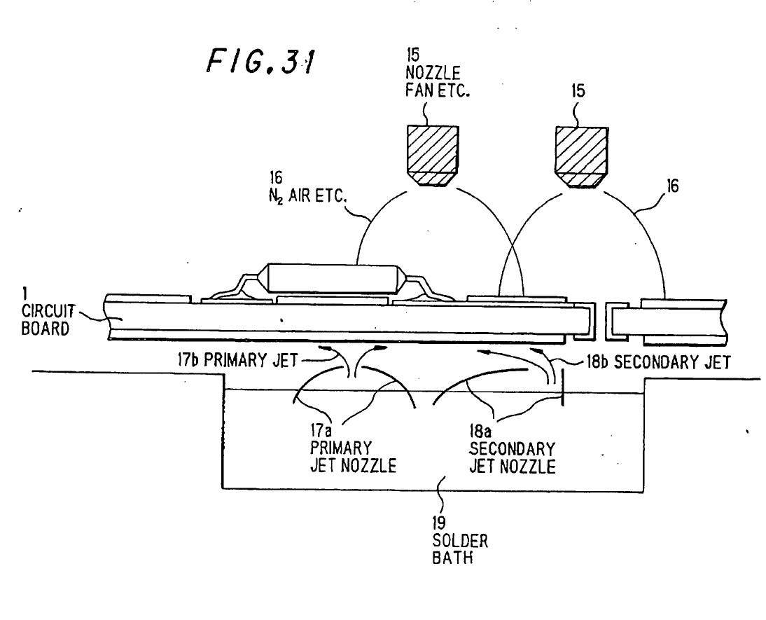

As shown in FIGS. 31 through 34, a circuit board according to the fourth embodiment of the present invention is constituted in such that a circuit board is cooled by the use of nitrogen gas or the like from the upper position thereof in case of wave-soldering, or a heat-resisting tape or resin is applied to the back of the circuit board, so that inflow of heat from flowing solder is suppressed, whereby fusion of a alloy layer formed in a lead joined site is prevented.

A specific constitution thereof will be described in detail in twenty-second and twenty-third examples mentioned hereunder.

[Embodiment 5]

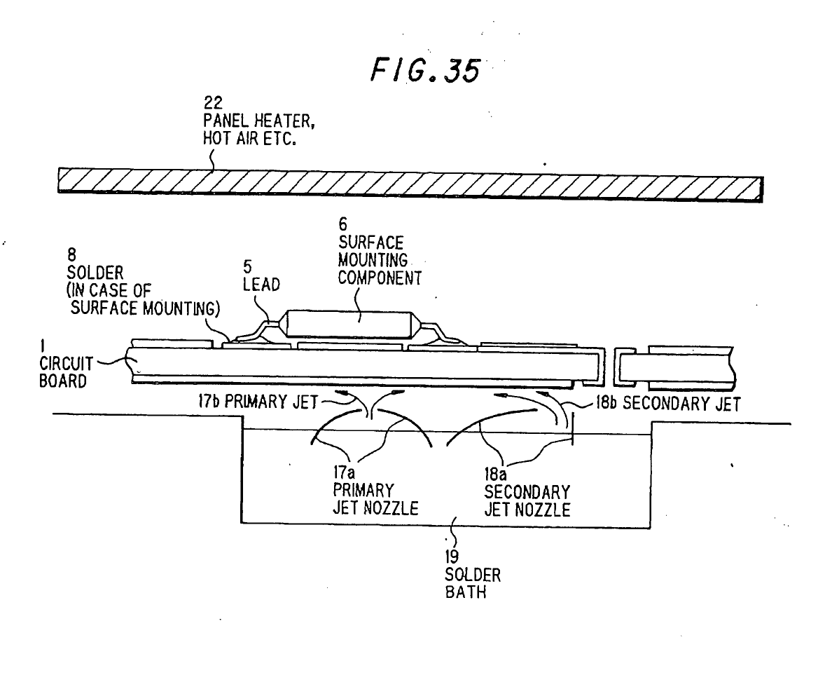

As shown in FIG. 35, a circuit board according to the fifth embodiment of the present invention is heated from the upper position thereof by means of a panel heater and the like to melt not only a alloy layer formed in a lead joined site, but also the whole solder in the lead joined site in case of wave-soldering, whereby exfoliation appearing in the case where only the alloy layer is molten is prevented.

A specific constitution thereof will be described in detail in a twenty-fourth example mentioned hereunder.

[Embodiment 6]

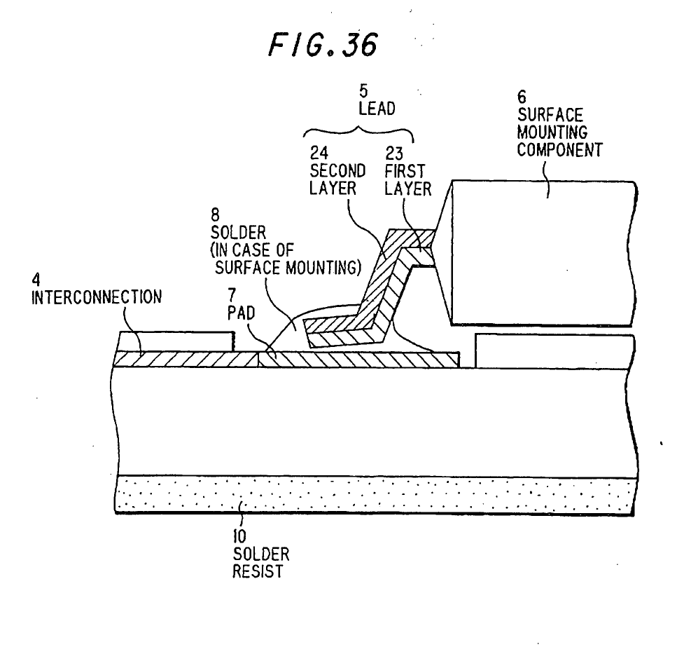

As shown in FIG. 36, a circuit board according to the sixth embodiment of the present invention is constituted in such that a lead of a surface mounting component is composed of two or more materials each having a different thermal expansion coefficient, and in this case, when a combination of these materials is selected in such a manner that the lead presses against the pad at the time of temperature rise of a joined site, whereby exfoliation of the lead is prevented even in the case where a alloy layer of the lead joined site was molten.

A specific constitution thereof will be described in detail in a twenty-fifth example mentioned hereunder.

[Embodiment 7]

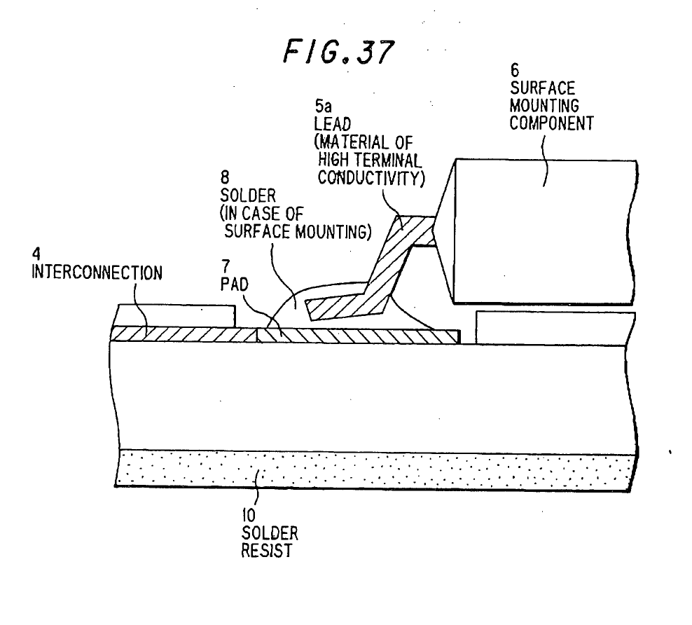

As shown in FIGS. 37 through 40, a circuit board according to the seventh embodiment of the present invention is constituted in such that a lead in a surface mounting component is prepared from a material having a high thermal conductivity so that heat flowed into a lead joined site is made to be easily transferred to a main body side of a surface mounting substrate, or a heat sink is disposed on the upper part of the surface mounting component to increase heat capacity, whereby fusion of a alloy layer formed on the lead joined site is prevented.

A specific constitution thereof will be described in detail in twenty-sixth and twenty-seventh examples mentioned hereunder.

### EXAMPLES

For the sake of more detailed description of the above-mentioned embodiments, examples of the present invention will be described hereinafter by referring to the accompanying drawings.

### Example 1

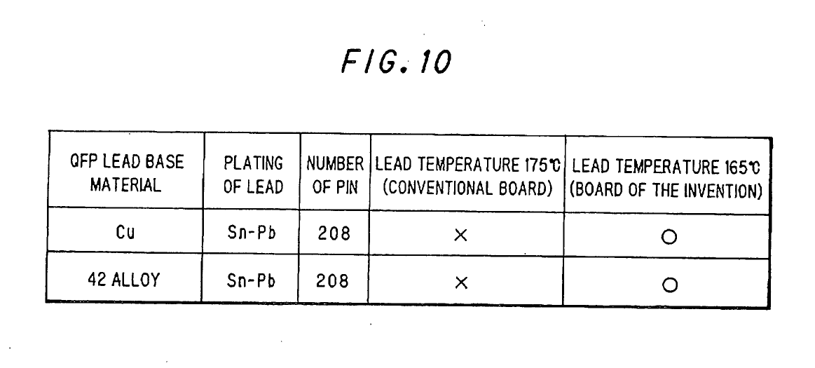

First, a circuit board according to the first example of the present invention is described by referring to FIG. 5 and FIGS. 10 through 12 wherein FIG. 5 is a sectional view showing schematically a part of the circuit board of the present example, and FIGS. 10 through 12 are ones each for explaining advantageous effects of the present example.

In the circuit board of the present example, as shown in FIG. 5, a surface mounting component 6 is mounted on a surface of the circuit board 1 in which a through hole 2a has been defined, and a lead 5 of the surface mounting component 6 is joined to a pad 7 of the circuit board 1 by means of solder 8. Furthermore, the through hole 2a is connected with the pad 7 by means of the land 3 and an interconnection 4.

The present example is characterized by that the through hole 2a represented by a heavy line is composed of a material such as nickel and palladium having a thermal conductivity being equal to or lower than a predetermined value, specifically a value equal to 100 W/m.K or less.

According to the above-described structure, a quantity of heat, which is transferred from the through hole 2a and solder 9 to be filled into the through hole 2a to the pad 7, the solder 8, and the lead 5 for the surface mounting component 6 through the interconnection in case of wave-soldering, can be reduced. As a result, exfoliation among the lead 5, the solder 8 or the pad 7, and the solder 8 can be suppressed.

On one hand, when the through hole 2a is prepared from, for example, nickel, the through hole 2a is difficult to be filled with the solder 9 as shown in FIG. 5, because nickel exhibits less wettability than that of copper with respect to solder. As a result, a quantity of heat transmitted to the pad 7, the solder 8, and the lead 5 can be reduced, whereby temperatures of the pad 7, the solder 8, and the lead 5 can be suppressed to, for example, a value equal to or less than 174° C. being a melting temperature of a alloy layer formed in an interface in between the pad 7 or the lead 5 and the solder 8. Hence, exfoliation appearing between the lead 5 and the solder 8 or the pad 7 and the solder 8 in a surface mounting component can be further suppressed.

Advantageous effects obtained in the case where electronic equipment is manufactured under such a condition that the temperatures of the above-described pad 7, solder 8, and lead 5 are maintained at 174° C. or less at the time of wave-soldering will be specifically commentated in conjunction with experimental data (FIGS. 10 through 12).

First, each surface mounting component (28 mm [symbol] , 0.5 mm terminal pitch, 208 pin QFP) was subjected to rewave-soldering on the circuit board 1 having a structure of the present example and a circuit board having a conventional structure by the use of lead-free solder (Sn-3.0Ag-0.5Cu). Thereafter, wave-soldering was conducted with respect to both the circuit boards of the present example and the prior art by the use of lead-free solder (Sn-3.0Ag-0.5Cu) as in the above case, whereby it was confirmed that existence of exfoliation of in each solder joined site of the above-described mounting components. In order to confirm exfoliation, an optical microscope and an SEM were used, and appearance observation and section observation were conducted.

As a result of the experiment, there is such a case in the circuit board having the conventional structure wherein its through hole is prepared from Cu that temperatures of the pad 7, the solder 8, and the lead 5 become higher than a temperature at which a alloy layer formed in the interface in between the solder 8 and the pad 7 is molten (175° C.) at the time of wave-soldering, so that exfoliation appears in the interface between the solder 8 and the lead 5, On the other hand, temperatures of the pad 7, the solder 8, and the lead 5 can be kept low (equal to or lower than 174° C.) at the time of wave-soldering in the circuit board 1 of the present example wherein the through hole 2a is prepared from nickel, because a thermal conductivity of the resulting through hole 2a is low so that no exfoliation was confirmed.

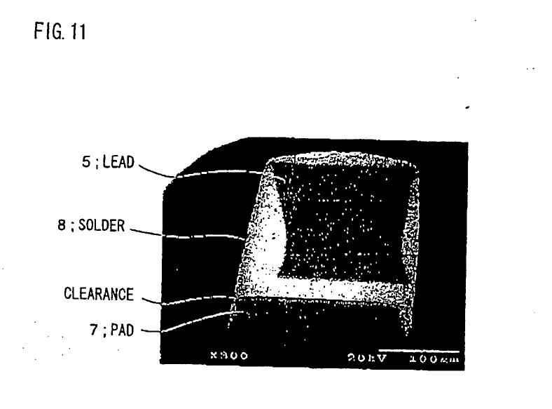

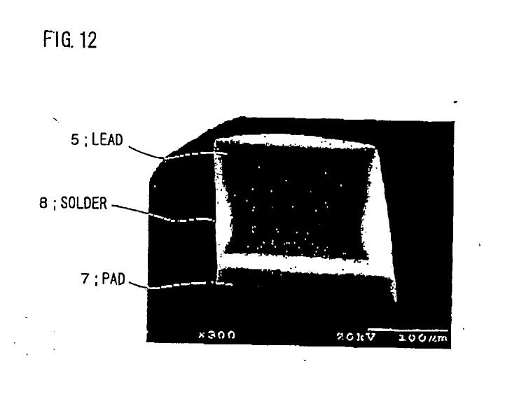

These results will be explained by referring to photographs each in section (a section taken along the line A-A′ of FIG. 5) shown in FIGS. 11 and 12.

As is apparent from FIG. 11 showing a section of the lead 5 under such condition that the lead 5 comes to be a temperature of 175° C. (the conventional structure), there is a clearance between the solder 8 and the pad 7, whereby there arises a problem of remarkable decrease in reliability of electronic equipment due to the clearance.

On the other hand, as is apparent from FIG. 12 showing a section of the terminal 5 under such condition that the lead 5 in the surface mounting component comes to be a temperature of 165° C. (the structure of the present example), a particularly abnormal state is not observed among the solder 8, the lead, and the pad 7, so that it is understood that the structure of the present example is effective for preventing exfoliation in the lead joined site of the surface mounting component.

In case of soldering electronic equipment where surface mounting type components and inserting type components are mixed by the use of lead-free solder, the through hole 2a has been prepared from a material exhibiting a low thermal conductivity in the circuit board 1 according to the present invention. As a result, heat flowing into a portion of the lead 5 at the time of wave-soldering may be reduced to suppress temperature rise, whereby electronic equipment having high reliability can be manufactured.

### Example 2

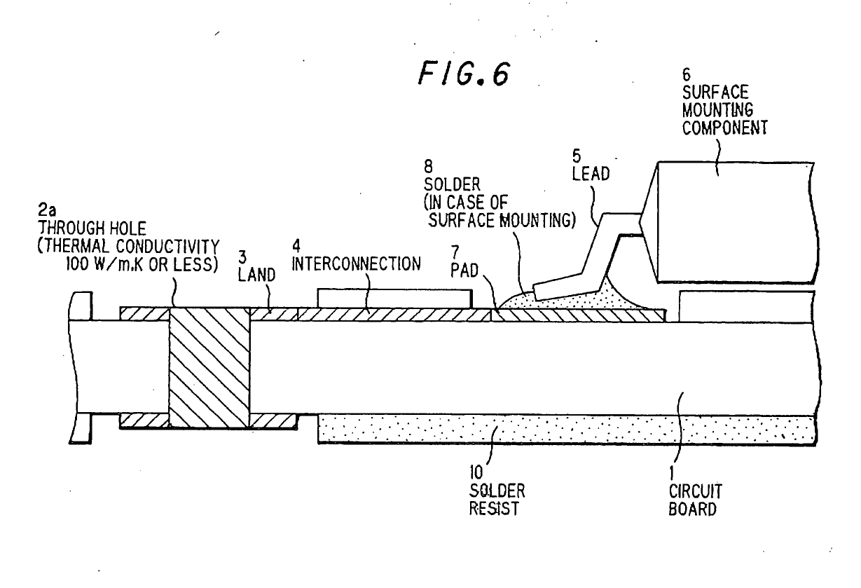

In the following, a circuit board according to the second example of the present invention will be described by referring to FIG. 6 wherein FIG. 6 is a sectional view showing schematically a part of the circuit board according to the second example.

The circuit board of the present example is characterized by that not only an inner wall of a through hole 2a, but also the whole interior thereof is filled with a material such as nickel, and palladium having a thermal conductivity equal to or less than a predetermined value (100 W/m.K).

In also the present example as in the above-described first example, heat conducted from the through hole 2a to the lead 5 can be suppressed at the time of wave-soldering, besides the through hole 2 is not filled with solder 9 in case of wave-soldering, so that a quantity of heat received directly from the solder 9 can be reduced. There is an advantage of suppressing exfoliation of lead joined site.

### Example 3

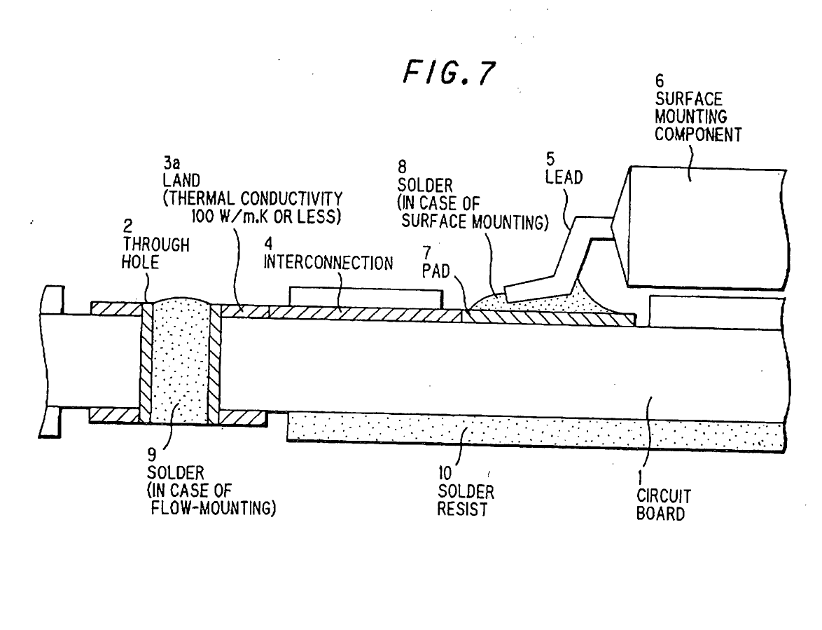

In the following, a circuit board according to the third example of the present invention will be described by referring to FIG. 7 wherein FIG. 7 is a sectional view showing schematically a part of the circuit board according to the third example.

The circuit board of the present example is characterized by that a land 3a situated around a through hole 2 is prepared from a material such as nickel, and palladium having a thermal conductivity equal to or less than a predetermined value (100 W/m.K).

In also the present example as in the above-described first and second examples, a quantity of heat transmitted from solder 9 and the through hole 2 via an interconnection 4 to a lead 5 can be reduced at the time of wave-soldering. Thus, there is an advantage of suppressing temperature rise in a lead joined site to prevent exfoliation thereof.

### Example 4

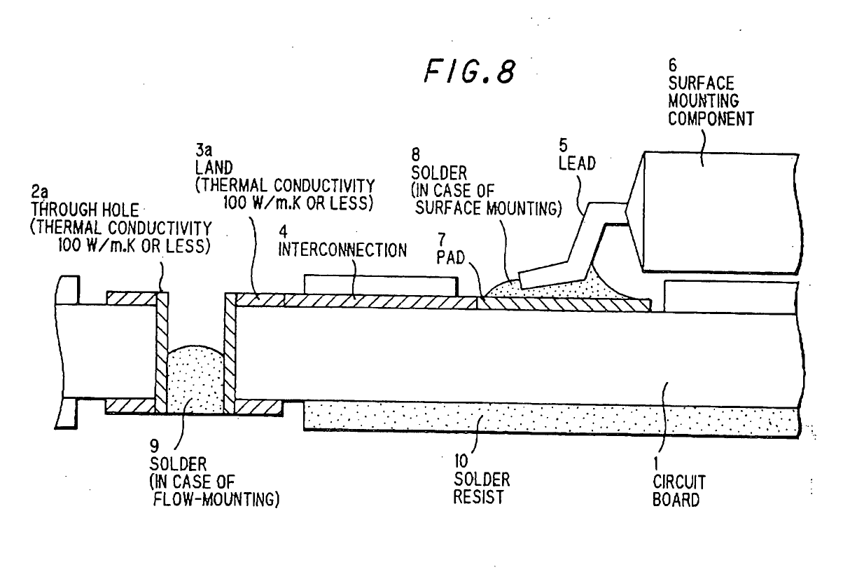

In the following, a circuit board according to the fourth example of the present invention will be described by referring to FIG. 8 wherein FIG. 8 is a sectional view showing schematically a part of the circuit board according to the fourth example.

The circuit board of the present example is characterized by that a through hole 2a and a land 3a are prepared from a material such as nickel having a thermal conductivity equal to or less than a predetermined value (100 W/m.K) and poor wettability with respect to solder.

When the through hole 2a is prepared from, for example, nickel, it exhibits poorer wettability than that of copper with respect to solder, so that it makes difficult that the through hole 2 is filled with solder 9, whereby a quantity of heat transmitted to a pad 7, solder 8, and a lead 5 decreases. In this case, as in the above-described first, second, and third examples, there is also an advantage of suppressing thermal conduction at the time of wave-soldering to prevent exfoliation of lead joined site.

### Example 5

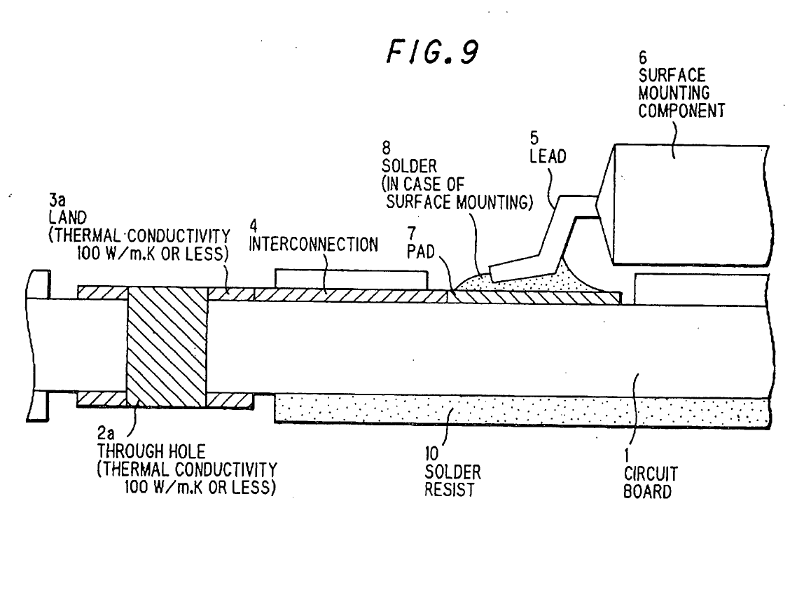

In the following, a circuit board according to the fifth example of the present invention will be described by referring to FIG. 9 wherein FIG. 9 is a sectional view showing schematically a part of the circuit board according to the fifth example.

The circuit board of the present example is characterized by that a through hole 2a and a land 3a are also prepared from a material having a thermal conductivity equal to or less than a predetermined value (100 W/m.K), respectively.

In this case, as in the above-described first through fourth examples, thermal conduction can be suppressed also, besides the through hole 2 is not filled with solder 9 at the time of wave-soldering, so that there is an advantage of reducing a quantity of heat received directly from the solder to prevent exfoliation of lead joined site.

### Example 6

A circuit board according to the sixth example of the present invention will be described by referring to FIG. 13 wherein FIG. 13 is a top view showing a state in which an electronic component has been mounted on the circuit board of the sixth example.

The circuit board of the present example is characterized by that a land 3, a pad 7, and an interconnection 4 are prepared from a material such as nickel, and palladium having a thermal conductivity being equal to or less than a predetermined value (100 W/m.K).

According to the above-described structure, a quantity of heat transmitted from a through hole 2 and solder 9 with which the through hole 2 is filled to the pad 7, the solder 8, and the lead 5 for a surface mounting component becomes smaller than that in the case where a copper interconnection is used, Hence, temperatures of the pad 7, the solder 8, and the lead 5 can be suppressed at a temperature equal to or less than 174° C. being a melting temperature of a alloy layer formed in an interface in between, for example, the pad 7 or the lead 5 and the solder 8, whereby exfoliation appearing between the lead 5 and the solder 8, or the pad 7 and the solder 8 can be suppressed. Furthermore, gold flashing or the like processing may be applied to the pad 7 with taking wettability of the pad 7 with respect to solder into consideration.

### Example 7

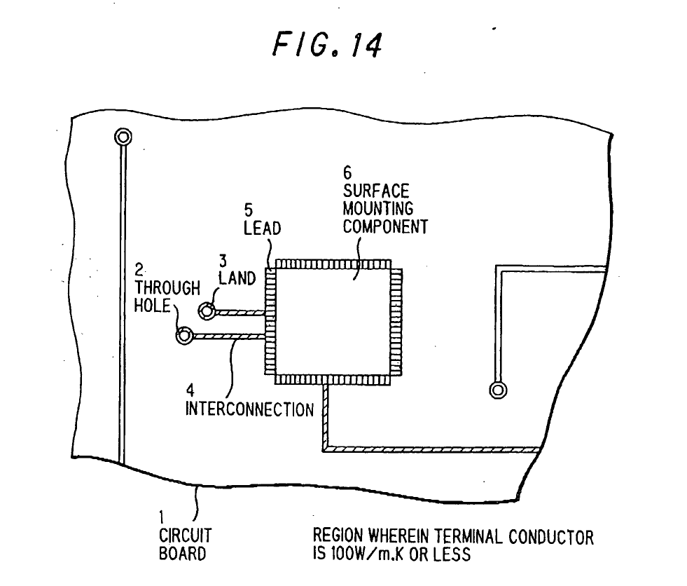

A circuit board according to the seventh example of the present invention will be described by referring to FIG. 14 wherein FIG. 14 is a top view showing a state in which an electronic component has been mounted on the circuit board of the seventh example.

The circuit board of the present example is characterized by that a land 3, an interconnection 4, and a site of a pad 7 (the site joined to a lead 5 of a surface mounting component 6) are prepared from a material having a thermal conductivity being equal to or less than a predetermined value (100 W/m.K).

In this case, there is also an advantage of suppressing thermal conduction at the time of wave-soldering to prevent exfoliation in a lead joined site.

Furthermore, gold flashing or the like processing may be applied to a surface of the pad 7 with taking wettability of the pad 7 with respect to solder 8 into consideration as in the above-described sixth example.

### Example 8

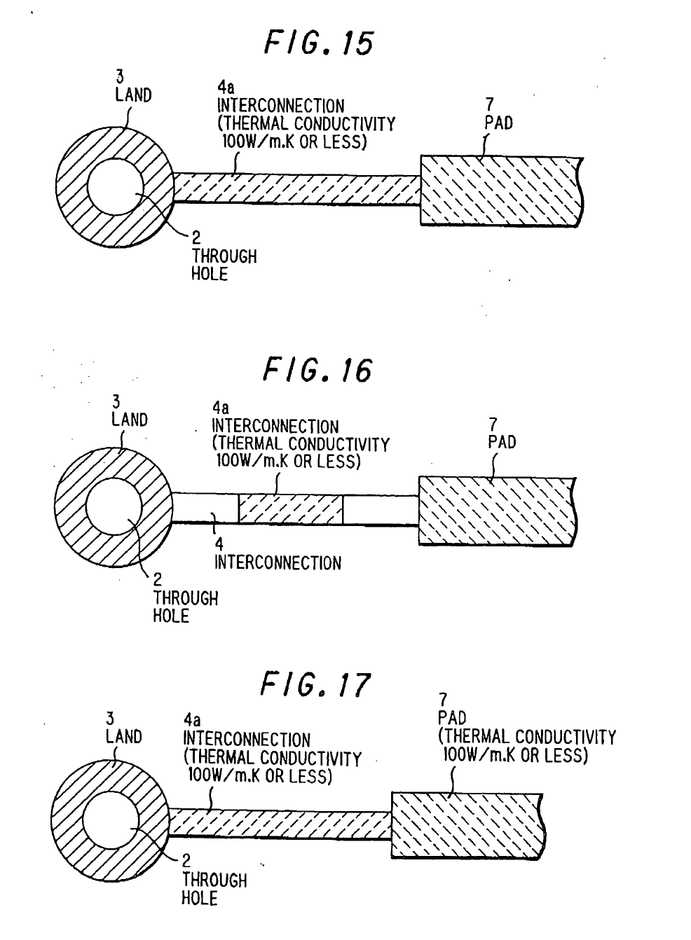

In the following, a circuit board according to the eighth example of the present invention will be described by referring to FIG. 15 wherein FIG. 15 is a plan view showing an enlarged region defined between a land 3 and a pad 7.

The circuit board of the present example is constituted in such that the whole section of an interconnection 4a formed between the land 3 and the pad 7 is prepared from a material exhibiting a thermal conductivity equal to or less than a predetermined value (100 W/m.K).

In this case, there is also an advantage of suppressing thermal conduction at the time of wave-soldering to prevent exfoliation in a lead joined site.

### Example 9

In the following, a circuit board according to the ninth example of the present invention will be described by referring to FIG. 16 wherein FIG. 16 is a plan view showing an enlarged region defined between a land 3 and a pad 7.

The circuit board of the present example is constituted in such that a partial section of an interconnection 4 formed between the land 3 and the pad 7 is prepared from a material exhibiting a thermal conductivity equal to or less than a predetermined value (100 W/m.K).

In this case, there is also an advantage of suppressing thermal conduction at the time of wave-soldering to prevent exfoliation in a lead joined site.

### Example 10

In the following, a circuit board according to the eleventh example of the present invention will be described by referring to FIG. 17 wherein FIG. 17 is a plan view showing an enlarged region defined between a land 3 and a pad 7a.

The circuit board of the present example is characterized by that the whole section of an interconnection 4a formed between the land 3 and the pad 7a as well as the pad 7a are prepared from a material exhibiting a thermal conductivity equal to or less than a predetermined value (100 W/m.K).

In this case, there is also an advantage of suppressing thermal conduction at the time of wave-soldering to prevent exfoliation in a lead joined site.

Furthermore, gold flashing or like processing may be applied to a surface of the pad 7 with taking wettability of the pad 7 with respect to solder into consideration.

### Example 11

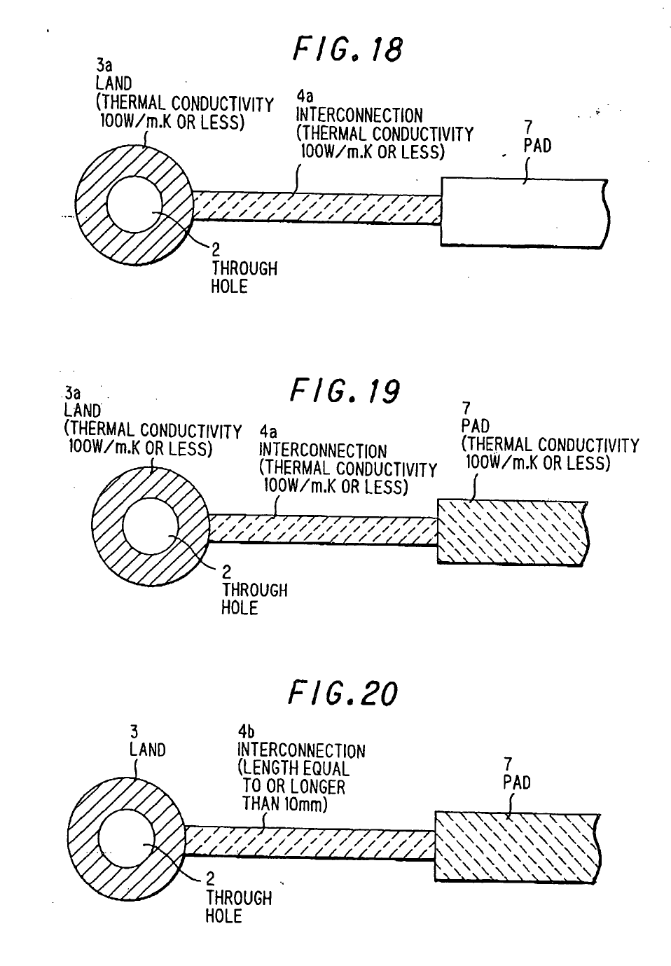

In the following, a circuit board according to the eleventh example of the present invention will be described by referring to FIG. 18 wherein FIG. 18 is a plan view showing an enlarged region defined between a land 3a and a pad 7.

The circuit board of the present example is characterized by that the whole section of an interconnection 4a formed between the land 3a and the pad 7 as well as the land 3a are prepared from a material exhibiting a thermal conductivity equal to or less than a predetermined value (100 W/m.K).

In this case, there is also an advantage of suppressing thermal conduction at the time of wave-soldering to prevent exfoliation in a lead joined site.

### Example 12

In the following, a circuit board according to the twelfth example of the present invention will be described by referring to FIG. 19 wherein FIG. 19 is a plan view showing an enlarged region defined between a land 3a and a pad 7a.

The circuit board of the present example is constituted in such that the whole section of an interconnection 4a formed between the land 3a and the pad 7a; the land 3a; and the pad 7a are prepared from a material exhibiting a thermal conductivity equal to or less than a predetermined value (100 W/m.K).

In this case, there is also an advantage of suppressing thermal conduction at the time of wave-soldering to prevent exfoliation in a lead joined site.

### Example 13

In the following, a circuit board according to the thirteenth example of the present invention will be described by referring to FIGS. 20, 24, and 41 wherein FIG. 20 is a plan view showing an enlarged region defined between a land 3 and a pad 7.

The circuit board of the present example is characterized by that a length of an interconnection 4b extending between the land 3 and the pad 7 is defined to be equal to or more than a predetermined value (10 mm).

According to the above-described constitution, a quantity of heat transmitted from a through hole 2 and solder 9 with which the through hole 2 is to be filled to the pad 7, solder 8, and a lead 5 for a surface mounting component through an interconnection 4b at the time of wave-soldering can be reduced in response to a length of the interconnection 4b. As a result, temperatures of the pad 7, the solder 8, and the lead 5 can be suppressed to the one equal to or less than 174° C. being a melting temperature of a alloy layer, whereby exfoliation appearing between the lead 5 and the solder 8 or the pad 7 and the solder 8 for the surface mounting component can be suppressed.

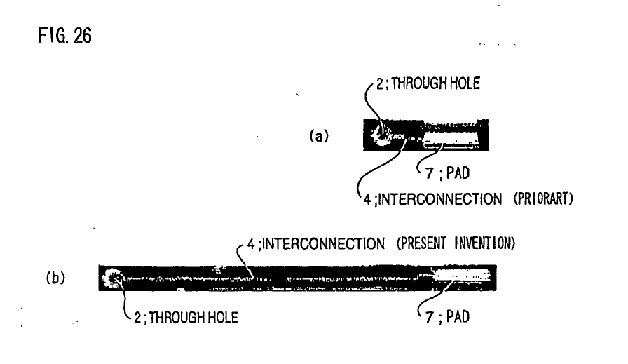

Advantages in the case where electronic equipment is manufactured under such a condition that temperatures of the above-described pad 7, solder 8, and lead 5 come to be a temperature equal to or less than 174° C. will be specifically described by employing experimental data shown in FIGS. 26(a) and 26(b).

First, each surface mounting component (28 mm [symbol] , 0.65 mm terminal pitch, 168 pin QFP) was reflow-soldered on a copper circuit board having a structure of the present example and a conventional structure by the use of lead-free solder (Sn-3.0Ag-0.5Cu). Thereafter, a wave-soldering step was applied with respect to both the circuit boards of the present example and the prior art by the use of lead-free solder (Sn-3.0Ag-0.5Cu) as in the above case, whereby it was confirmed that existence of exfoliation of in each solder joined site of the above-described mounting components. In order to confirm exfoliation, an optical microscope and an SEM were used, and appearance observation and section observation were conducted.

As a result of the experiment, a temperature of a lead became 189° C. in an interconnection 4a having 3 mm length (the conventional example) shown in FIG. 26(a), so that exfoliation appeared between a lead 5 and solder 8 as well as between a pad 7 and the solder 8.

On the other hand, a temperature of a lead 5 became 168° C. in an interconnection 4b having 11 mm length (the present example), so that no exfoliation is observed, whereby advantages of the present example could be confirmed.

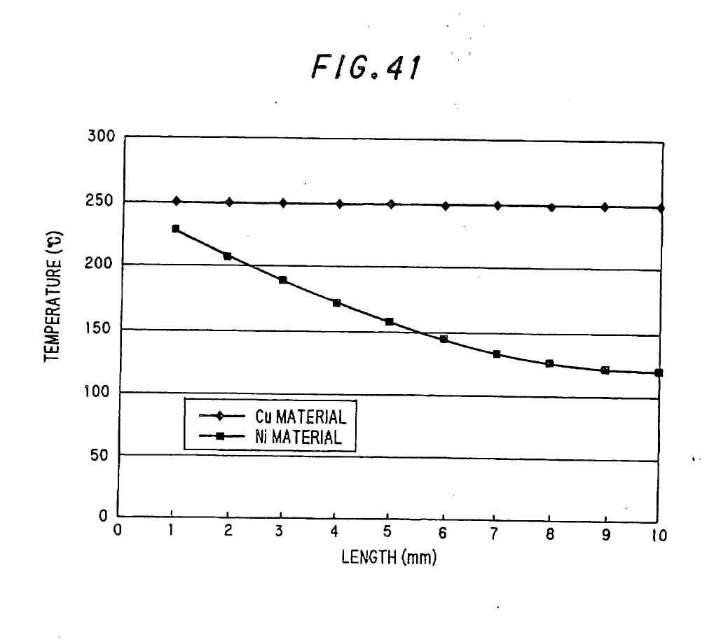

Moreover, a relationship between a length of interconnection and a temperature in the case where a Cu material and a Ni material are used for the interconnection 4 is represented in FIG. 41 wherein an initial temperature of the interconnection 4 was set to 100° C., then, a temperature at either end thereof was elevated to 250° C., and a temperature at the opposite end thereof after lapse of four seconds was determined by a simulation.

As is apparent from FIG. 41, when the Cu material having a high thermal conductivity (represented by solid black circular marks) is used for the interconnection 4, heat transmits rapidly through the interconnection 4, so that a temperature at either end of the interconnection becomes equal to that of the opposite end.

On the other hand, when the Ni material having a low thermal conductivity (represented by solid black square marks) is used for the interconnection 4, it is understood that conduction of heat is suppressed, so that a temperature reaches a substantially constant value in a length of around 10 mm, and a temperature at the opposite end of the interconnection 4 is kept at a low value. From these results, it was confirmed that a length of interconnection is preferably 10 mm or longer.

### Example 14

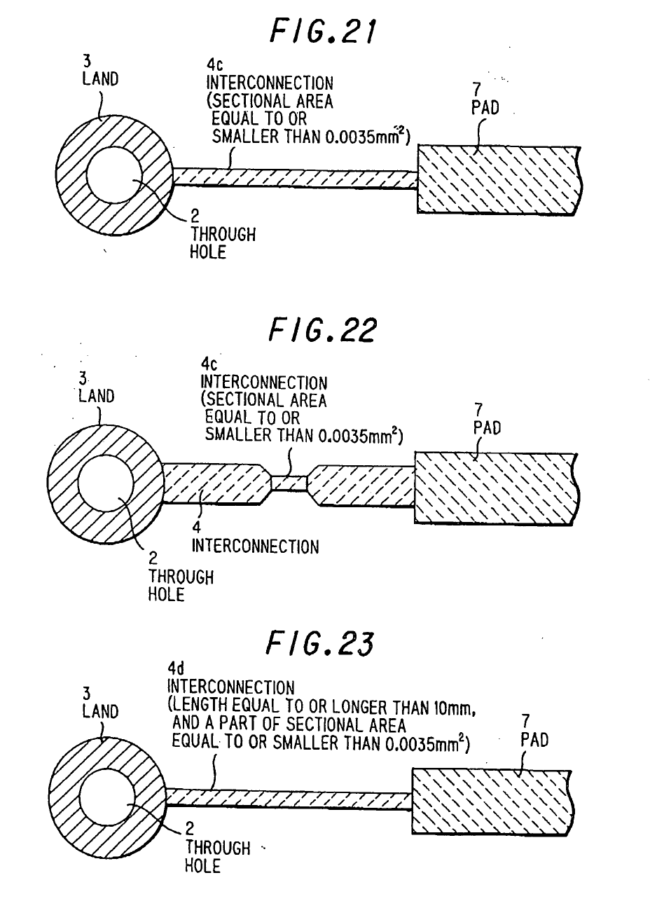

In the following, a circuit board according to the fourteenth example of the present invention will be described by ref erring to FIG. 21 wherein FIG. 21 is a plan view showing an enlarged region defined between a land 3 and a pad 7.

The circuit board of the present example is characterized by that an interconnection 4c is formed so as to have a sectional area of 0.0035 mm² or less.

In this case, there is also an advantage of suppressing thermal conduction at the time of wave-soldering to prevent exfoliation in a lead joined site as in the thirteenth example.

### Example 15

In the following, a circuit board according to the fifteenth example of the present invention will be described by referring to FIG. 22 wherein FIG. 22 is a plan view showing an enlarged region defined between a land 3 and a pad 7.

The circuit board of the present example is characterized by that only a partial section of an interconnection 4c is formed so as to have a sectional area of 0.0035 mm² or less.

In this case, the same results are also obtained as in the thirteenth example and the fourteenth example, and there is an advantage of suppressing thermal conduction at the time of wave-soldering to prevent exfoliation in a lead joined site.

### Example 16

In the following, a circuit board according to the sixteenth example of the present invention will be described by referring to FIG. 23 wherein FIG. 23 is a plan view showing an enlarged region defined between a land 3 and a pad 7.

The circuit board of the present example is characterized by that an interconnection 4d is formed in such that an overall length thereof is 10 mm or longer, and a sectional area thereof is 0.0035 mm² or less.

In this case, the same results are also obtained as in the thirteenth example through the fifteenth example, and there is an advantage of suppressing thermal conduction at the time of wave-soldering to prevent exfoliation in a lead joined site.

### Example 17

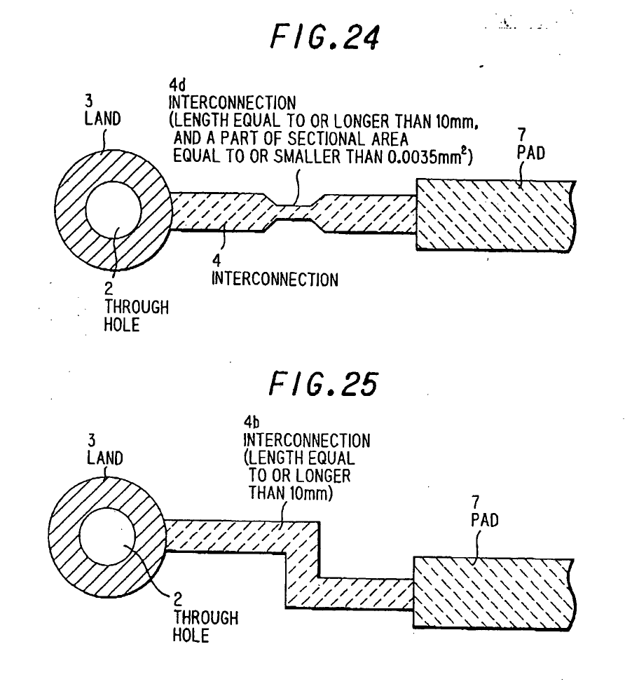

In the following, a circuit board according to the seventeenth example of the present invention will be described by referring to FIG. 24 wherein FIG. 24 is a plan view showing an enlarged region defined between a land 3 and a pad 7.

The circuit board of the present example is characterized by that an interconnection 4d is formed in such that an overall length thereof is 10 mm or longer, and a part of sectional area thereof is 0.0035 mm² or less.

In this case, there is also an advantage of suppressing thermal conduction at the time of wave-soldering to prevent exfoliation of a lead joined site.

### Example 18

In the following, a circuit board according to the eighteenth example of the present invention will be described by referring to FIG. 25 wherein FIG. 25 is a plan view showing an enlarged region defined between a land 3 and a pad 7.

The circuit board of the present example is characterized by that an interconnection 4b is formed in such that an overall length thereof is 10 mm or longer in the case where the interconnection 4b does not extend linearly between the land 3 and the pad 7.

In this case, there is also an advantage of suppressing thermal conduction at the time of wave-soldering to prevent exfoliation in a lead joined site.

It is to be noted that a pattern of the interconnection is not limited to that of FIG. 25, but the whole area or a part of sectional area of the interconnection 4b maybe made to be 0.0035 mm² or less, so that thermal conduction can be suppressed more effectively, as a matter of course.

### Example 19

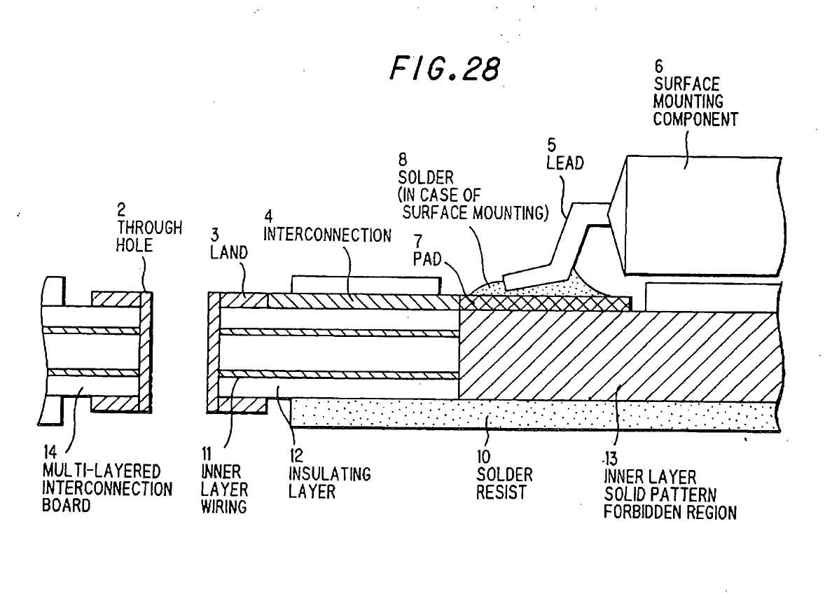

A circuit board according to the nineteenth example of the present invention will be described by referring to FIGS. 27 and 28 wherein FIG. 27 is a top view showing a state in which an electronic component has been mounted on the circuit board of the nineteenth example, and FIG. 28 is a sectional view taken along the line B-B′.

Since a method for manufacturing circuit boards is the same as that of the prior art, an explanation therefor will be omitted.

The circuit board of the present example is characterized by that a part of the circuit board immediately below a mounting position of a surface mounting component 6 shown in FIGS. 27 and 28 is made to be an inner layer solid pattern forbidden region 13.

According to the above-described structure, a quantity of heat transmitted from a through hole 2 and solder 9 with which the through hole 2 is to be filled to a pad 7, solder 8, and lead 5 through an inner layer wiring 11 and an insulating layer 12 at the time of wave-soldering is reduced. Furthermore, a quantity of heat transferred from solder being in contact with a solder resist 10 to the insulating layer 12 and the inner layer wiring 11 at the time of wave-soldering decreases also, so that a temperature in a site of the inner layer solid pattern forbidden region 13 in the circuit board lowers, whereby temperatures of the pad 7, the solder 8, and the lead 5 lower also.

Thus, when the temperatures of the pad 7, the solder 8, and the lead 5 are suppressed to a temperature equal to or lower than 174° C. being a melting temperature of a alloy layer, exfoliation appearing between the lead 5 and the solder 8 or the pad 7 and the solder 8 for the surface mounting component can be suppressed.

### Example 20

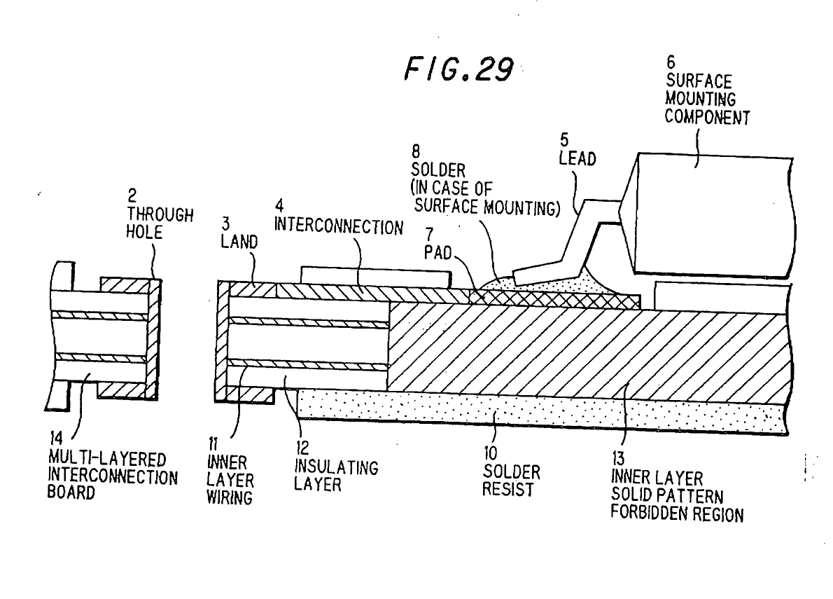

A circuit board according to the twentieth example of the present invention will be described by referring to FIG. 29.

In the circuit board shown in FIG. 29, an inner layer solid pattern forbidden region 13 is formed so as to expand over a pad end 7b. In this respect, the inner layer solid pattern forbidden region 13 is sufficient to include an area extending from the inside of the pad end 7b.

In this case, there is also an advantage of suppressing thermal conduction at the time of wave-soldering to prevent exfoliation in a lead joined site.

### Example 21

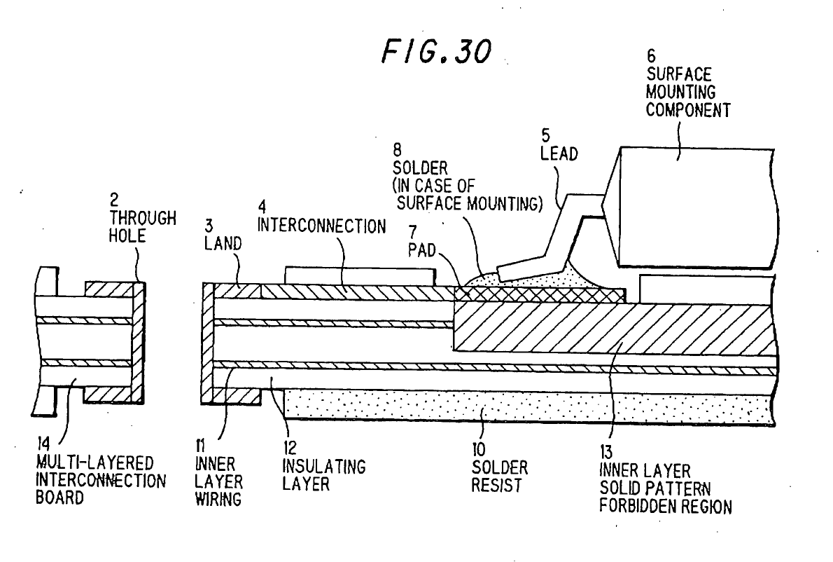

A circuit board according to the twenty-first example of the present invention will be described by referring to FIG. 30.

In the circuit board shown in FIG. 30, an inner layer solid pattern forbidden region 13 is applied to a part of an inner wiring 11.

In this case, there is also an advantage of suppressing thermal conduction at the time of wave-soldering to prevent exfoliation in a lead joined site.

### Example 22

A circuit board according to the twenty-second example of the present invention will be described by referring to FIG. 31.

The circuit board according to the present example is characterized by that a surrounding area of a lead, and a surrounding area of solder in a lead joined site of a surface mounting component, or an interconnection, a through hole, a land and the like are cooled.

Namely, for example, nozzles or fans 15 are disposed on the side opposite to a solder bath 19 through the circuit board 1, and nitrogen or air 16 is blown at the time of wave-soldering as shown in FIG. 31.

When such a surrounding area of a lead, and a surrounding area of solder in a lead joined site of the surface mounting component, or the interconnection, the through hole, the land and the like are cooled, temperature rise of solder in the lead joined site can be suppressed.

As a result, there is an advantage of preventing fusion of a alloy layer formed in an interface in between the lead or the pad and the solder to suppress exfoliation in the lead joined site.

### Example 23

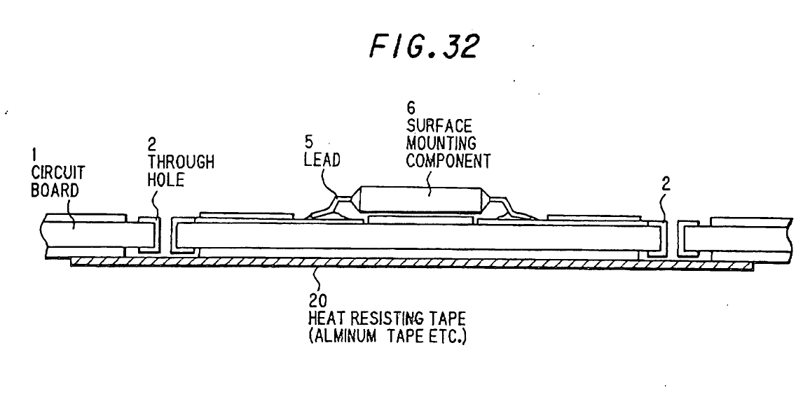

A circuit board according to the twenty-third example of the present invention will be described by referring to FIGS. 32 through 34.

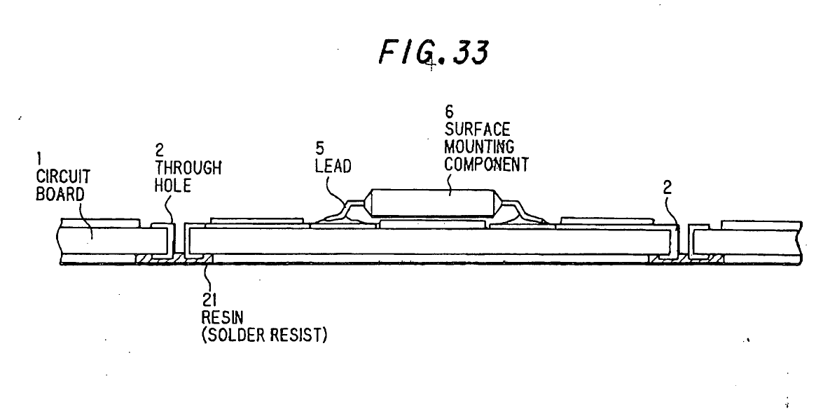

The circuit board according to the present example is constituted in such that either a region immediately below a surface mounting type component 6, a lead 5, and solder 8 on the surface where these members have not been mounted that is opposite to the surface on which the surface mounting component 6 for the circuit board 1 has been mounted, or a region involving any of or all of a through hole 2, and a land 3 is covered with either a heat-resisting tape 20 (aluminum tape) for reducing thermal conduction, or a resin or a solder resist 21 having a low thermal conductivity as shown in FIGS. 32 and 33.

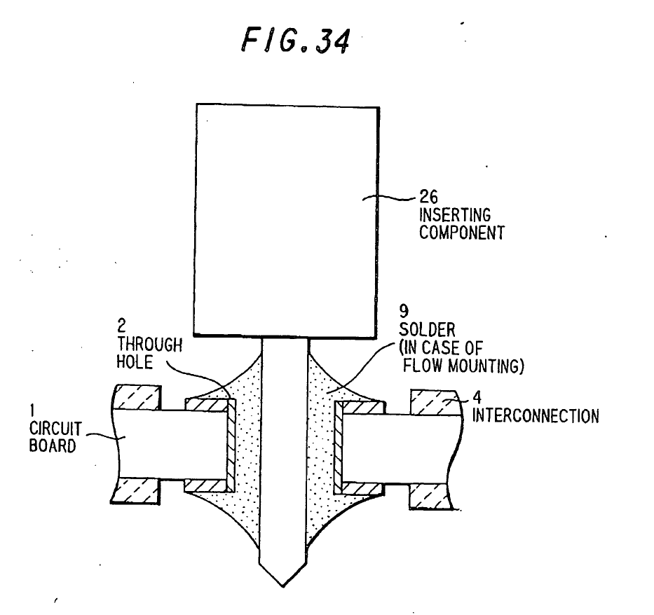

Although only a vicinity of each region on which the surface mounting component 6 is to be mounted is shown in FIGS. 32 and 33, a region on which an inserting component 26 is to be mounted by means of wave-soldering is also formed as shown in FIG. 34.

Accordingly, it is preferred that the heat-resisting tape 20 or the resin 21 is applied to at least a region except for the through hole 2 in which the inserting component 26 is to be mounted. However, even if the resin 21 is applied to only a region of the through hole 2 to be joined to the surface mounting component 6, flowing of solder 9 into the through hole 2 can be prevented, whereby an advantage of suppressing thermal conduction can be expected.

According to the constitution of the present example, as described above; there are such advantages that thermal conduction at the time of wave-soldering can be suppressed, that flowing of solder into the through hole to be joined to a lead of the surface mounting component 6 can be suppressed, and that exfoliation in a lead joined site can be prevented.

### Example 24

A circuit board according to the twenty-fourth example of the present invention will be described by referring to FIG. 35.

The circuit board according to the present example is characterized by that temperatures of a surrounding area of a lead 5 and a surrounding area of solder 8 are elevated.

A heating means such as a panel heater, and an air heater is disposed on the side opposite to a solder bath 19 through the circuit board 1 at the time of wave-soldering as shown in FIG. 35, whereby a temperature of the whole circuit board 1, an ambient temperature thereof, or temperatures of both the surrounding areas of the lead 5 and the solder 8 are elevated. Thus, not only a alloy layer formed in a lead joined site, but also the whole solder 8 are molten, resulting in an advantage of suppressing exfoliation in the lead joined site due to warpage of a mounting component and the like.

### Example 25

A circuit board according to the twenty-fifth example of the present invention will be described by referring to FIG. 36.

The circuit board according to the present example is characterized by that a lead 5 for surface mounting component 6 to be mounted on the circuit board 1 is made to have two-layered structure wherein a first layer 23 disposed on the side of the circuit board 1 is prepared by a material such as Ni having a large coefficient of thermal expansion, and a second layer 24 to be situated on the first layer 23 is prepared by a material such as Cu having a small coefficient of thermal expansion.

In such arrangement as described above, a force acts in a direction wherein the lead 5 is pushed against the side of the circuit board 1 at the time of wave-soldering due to differences in thermal expansion coefficients by heating, so that there is an advantage of suppressing exfoliation in a lead joined site.

In the above arrangement, any combination of materials for the first and second layers may be applied so far as the second layer 24 has a larger coefficient of thermal expansion than that of the first layer 23. In this connection, the same advantageous effect can be achieved by an arrangement in which the first layer 23 is a 42 alloy, and the second layer 24 is Ni.

Furthermore, the lead 5 may be a laminated structure having two or more layers.

Moreover, it is possible to electrodeposit either of the first and second layers on either side of the other layer that may be the first layer or the second layer.

Besides, the above-described modification is not limited to such case wherein the whole lead 5 is composed of a laminated structure prepared from materials having different coefficients of thermal expansion, but only a bent portion of the lead 5 may be prepared partially from materials having different coefficients of thermal expansion (for example, the bent portion on the upper side is prepared by a material having a large thermal expansion coefficient, while the bent portion on the lower side is prepared by another material having a small thermal expansion coefficient) thereby obtaining a structure by which the lead 5 is pushed against the side of the circuit board 1 at the time of rising temperature.

### Example 26

A circuit board according to the twenty-sixth example of the present invention will be described by referring to FIG. 37.

The circuit board according to the present example is characterized by that a lead 5a of a surface mounting component 6 to be mounted on the circuit board 1 is prepared by a material having a high thermal conductivity such as Ag exhibiting a higher thermal conductivity (thermal conductivity of 422 W/m.K at 100° C.) than that of Cu (thermal conductivity of 395 W/m.K at 100° C.), which is usually employed.

In the above-described arrangement, heat flowed into solder 8 in a lead joined site can be efficiently released to the side of the surface mounting component 6 through the lead 5a at the time of wave-soldering, so that there is an advantage of suppressing temperature rise in the lead joined site to prevent fusion of an alloyed layer, whereby exfoliation in the lead joined site can be suppressed.

### Example 27

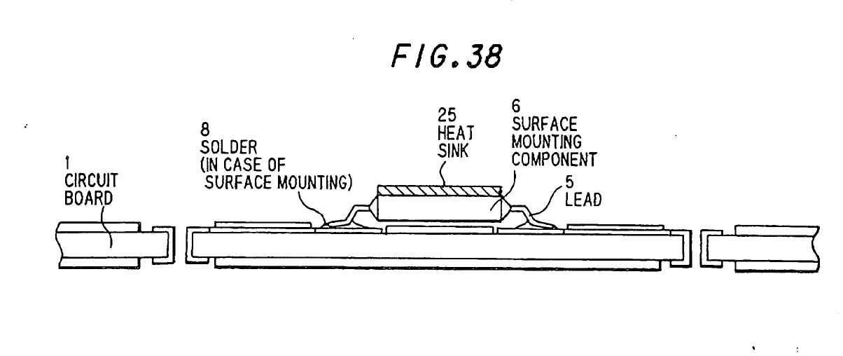

In the following, a circuit board according to the twenty-seventh example of the present invention will be described by referring to FIGS. 38 through 40.

The circuit board of the present example is characterized by that a member such as a heat sink having a high heat capacity is disposed on a surface mounting component 6 to be mounted on a circuit board 1, whereby heat flowed into a lead joined site at the time of wave-soldering is absorbed to suppress temperature rise of solder 8.

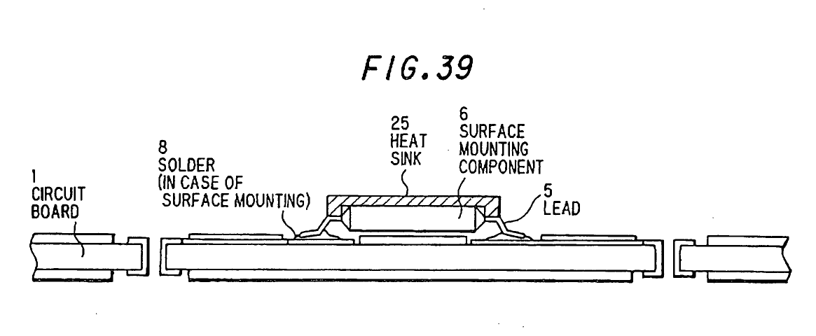

More specifically, there are a structure wherein a heat sink 25 is disposed only on the surface mounting component 6, whereby a heat capacity of the component main body is increased to make absorption of heat from the lead 5 easy as shown in FIG. 38; another structure wherein end portions of the heat sink 25 are made to be in contact with the lead 5 as shown in FIG. 39; and a further structure wherein end portions of the heat sink 25 are made to be in contact with the solder 8, whereby absorption of heat is further promoted.

As described above, as a result of providing the heat sink 25, heat flowed into the solder 8 in the lead joined site can be efficiently absorbed by the surface mounting component 6 through the lead 5, so that there is an advantage of suppressing temperature rise of the solder 8 to prevent exfoliation in the lead joined site.

Furthermore, the heat sink 25 has a function as a weight other than that of absorbing heat flowed from the lead 5. As a result, when a alloy layer or the solder 8 is molten at the time of wave-soldering, the heat sink 25 exhibits a function for pushing the lead 5 against the side of the circuit board 1, whereby it becomes possible to further suppress exfoliation in the lead joined site.

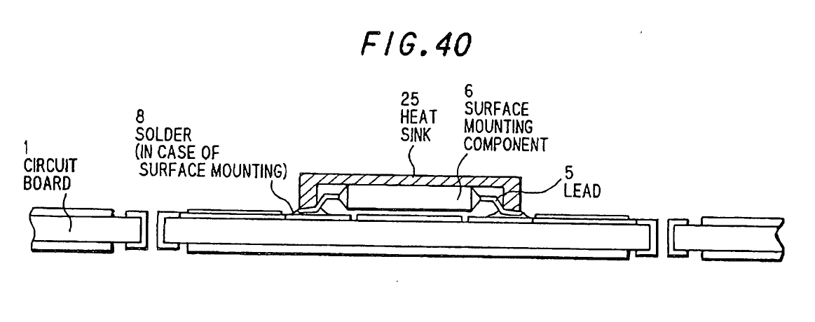

The heat sink 25 may be prepared from an arbitrary material such as metal having a large heat capacity. In the case where the heat sink 25 is prepared from a metal, the lead 5 may be short-circuited in either manner of FIGS. 39 and 40. Accordingly, it is desired to mount the heat sink 25 only at the time of wave-soldering. Alternatively, a heat sink of an insulating member such as ceramics may be applied.

In a manner shown in FIG. 40, since the heat sink 25 is in contact with the solder 8, it is preferred to select a material having poor wettability with respect to solder as a member of the heat sink.

It is to be noted that the above-described examples may be applied singly or also in a suitable combination thereof.

As described above, the present invention provides a basic constitution of a circuit board including a through hole, an electrode pad for surface mounting component, and an interconnection for connecting them wherein the surface mounting component is mounted on the electrode pad by the use of lead-free solder, characterized by that at least one member selected from the group consisting of the through hole, the land, and the interconnection is prepared by a material having a thermal conductivity equal to or less than a predetermined value (100 W/m.K)

As a result, according to the above-described constitution of the invention, such an advantage that a quantity of heat transmitted from the through hole and the solder with which the through hole is filled to the electrode pad at the time of wave-soldering is reduced, whereby temperature rise in the electrode of the surface mounting component is suppressed to prevent exfoliation in a lead joined site is obtained.

Furthermore, the present invention provides another basic constitution of a circuit board including a through hole, an electrode pad for surface mounting component, and an interconnection for connecting them wherein the surface mounting component is mounted on the electrode pad by the use of lead-free solder, characterized by that a length of the interconnection is made to be equal to or more than a predetermined value (10 mm), or a sectional area of the interconnection is adapted to be equal to or less than a predetermined value (0.0035 mm).

As a result, according to the above-described constitution of the invention, such an advantage that a quantity of heat transmitted from the through hole and the solder with which the through hole is filled to the electrode pad at the time of wave-soldering is reduced, whereby temperature rise in the electrode of the surface mounting component is suppressed to prevent exfoliation in a lead joined site is obtained.

Moreover, the present invention provides a further basic constitution of a circuit board including a through hole, an electrode pad for surface mounting component, and an interconnection for connecting them wherein the surface mounting component is mounted on the electrode pad by the use of lead-free solder, characterized by that the whole or a part of an inner layer of the circuit board situated immediately below the surface mounting component is adapted to be a layout forbidden region for solid pattern.

As a result, according to the above-described constitution of the invention, such an advantage that a quantity of heat transmitted from the through hole and the solder with which the through hole is filled to the electrode pad through the inner layer solid pattern and an insulating layer at the time of wave-soldering is reduced, whereby temperature rise in the electrode of the surface mounting component is suppressed to prevent exfoliation in a lead joined site is obtained.

Besides, when temperature rise of an electrode in a surface mounting component is suppressed to a temperature equal to or less than 174° C. being a melting temperature of a alloy layer formed in an interface in between a lead of the surface mounting component or an electrode pad of a circuit board and solder, exfoliation in a lead joined site, which will occur due to wave-soldering after surface-mounting of the component was conducted with the use of lead-free solder, can be suppressed in the circuit board.

The presently disclosed embodiments are therefore considered in all respects to be illustrative and not restrictive. The scope of the invention is indicated by the appended claims rather than the foregoing description, and all changes that come within the meaning and range of equivalents thereof are intended to be embraced therein.

1. A circuit board for mounting a surface mounting component, wherein:
the circuit board has an upper surface on which the surface mounting component is to be mounted and a lower surface to be subjected to wave-soldering, the circuit board is composed such that, when the wave-soldering is conducted while joining a terminal of the surface mounting component and the electrode pad of the circuit board by using lead-free solder, the joined site of the terminal of the surface mounting component and the electrode pad of the circuit board is made not to be equal to or higher than a melting temperature of a alloy layer formed at the interface of the terminal or electrode pad and the lead-free solder, the melting temperature of the alloy layer being lower than that of the lead-free solder;
said circuit board is composed such that the temperature of a joined site of a terminal of said surface mounting component and an electrode pad of said circuit board is controlled not to be equal to or more than a melting temperature of a alloy layer formed in said joined site.

2. A circuit board involving a alloy layer made of at least an element of solder, a terminal of a surface mounting component to be mounted on a surface of the circuit board, an electrode pad of said circuit board in either an interface residing in between said terminal and said solder, or an interface residing in between said electrode pad and said solder in a joined site of said terminal and said electrode pad with the solder, comprising:
a means for suppressing conduction of heat being disposed on a thermal conduction path extending from the back of said circuit board on the side opposite to the side on which said surface mounting component has been mounted to said electrode pad, so that said suppressing means allows the temperature of said joined site to be kept at a temperature equal to or less than a melting temperature of said alloy layer.

3. A circuit board as claimed in claim 1, wherein:
said alloy layer includes a ternary alloy consisting of tin and silver contained in said solder, and lead contained in said terminal or said electrode pad.

4. A circuit board as claimed in claim 2, wherein:
said alloy layer includes a ternary alloy consisting of tin and silver contained in said solder, and lead contained in said terminal or said electrode pad.

5. A circuit board as claimed in claim 1, wherein:
at least one of a through hole joined to said electrode pad and a land foamed around a surrounding of said through hole is made of a material with a thermal conductivity of 100 W/m ∘ K or less.

6. A circuit board as claimed in claim 2, wherein:
at least one of a through hole joined to said electrode pad and a land formed around a surrounding of said through hole is made of a material with a thermal conductivity of 100 W/m ∘ K or less.

7. A circuit board as claimed in claim 3, wherein:
at least one of a through hole joined to said electrode pad and a land formed around a surrounding of said through hole is made of a material with a thermal conductivity of 100 W/m ∘ K or less.

8. A circuit board as claimed in claim 5, wherein:
said through hole to be joined to said electrode pad is filled with a material with a thermal conductivity of 100 W/m ∘ K or less.

9. A circuit board as claimed in claim 6, wherein:
said through hole to be joined to said electrode pad is filled with a material with a thermal conductivity of 100 W/m ∘ K or less.

10. A circuit board as claimed in claim 7, wherein:
said through hole to be joined to said electrode pad is filled with a material with a thermal conductivity of 100 W/m ∘ K or less.

11. A circuit board as claimed in claim 5, wherein:
at least part of an interconnection for connecting between said through hole and said electrode pad is made of a material with a thermal conductivity of 100 W/m° K. or less.

12. A circuit board as claimed in claim 6, wherein:
at least part of an interconnection for connecting between said through hole and said electrode pad is made of a material with a thermal conductivity of 100 W/m° K. or less.

13. A circuit board as claimed in claim 7, wherein:
at least part of an interconnection for connecting between said through hole and said electrode pad is made of a material with a thermal conductivity of 100 W/m° K. or less.

14. A circuit board as claimed in any one of claims 5 to 13, wherein: said material is nickel or palladium.

15. A circuit board as claimed in claim 5, wherein:
an interconnection for connecting between said through hole and said electrode pad has a length of 10 mm or longer,

16. A circuit board as claimed in claim 6, wherein:
an interconnection for connecting between said through hole and said electrode pad has a length of 10 mm or longer.

17. A circuit board as claimed in claim 7, wherein:
an interconnection for connecting between said through-hole and said electrode pad has a length of 10 mm or longer.

18. A circuit board as claimed in claim 5, wherein:
at least part of an interconnection for connecting between said through hole and said electrode pad has a sectional area of 0.0035 mm² or less.

19. A circuit board as claimed in claim 6, wherein:
at least part of an interconnection for connecting between said through hole and said electrode pad has a sectional area of 0.0035 mm² or less.

20. A circuit board as claimed in claim 7, wherein:
at least part of an interconnection for connecting between said through hole and said electrode pad has a sectional area of 0.0035 mm² or less.

21. A circuit board as claimed in claim 1, wherein:
said circuit board is composed of a multi-layered interconnection board and has a region where formation of a solid pattern is forbidden, said region including whole or part of an inner layer of the multi-layered interconnection board located around just below a position where said surface mounting component is mounted.

22. A circuit board as claimed in claim 2, wherein:
said circuit board is composed of a multi-layered interconnection board and has a region where formation of a solid pattern is forbidden, said region including whole or part of an inner layer of the multi-layered interconnection board located around just below a position where said surface mounting component is mounted.

23. A surface mounting component to be mounted on a circuit board, comprising—
a terminal at least part of which is composed of multiple layers of a plurality of materials with different thermal expansion coefficients, said multiple layers having a layer of a material with a small thermal expansion coefficient on the side facing said circuit board;
wherein said terminal is deformed in a direction along which said terminal pushes down said circuit board when temperature rises in wave-soldering the back of said circuit board.

24. A surface mounting component as claimed in claim 23, wherein:
said terminal is provided with a bent portion composed of a layer that is of a material with a thermal expansion coefficient different from that of the material of a main portion of said terminal.

25. A surface mounting component to be mounted or a circuit board, comprising:
a terminal at least the surface layer of which is made of a predetermined material with a thermal conductivity greater than that of Cu, so that heat flowing into the joined site of said terminal is promoted to move to the main body of said surface mounting component in wave-soldering on the back of said circuit board.

26. A surface mounting component as claimed in claim 25, wherein: said predetermined material contains Ag.

27. Electronic equipment, comprising:
a circuit board for mounting a surface mounting component, wherein:
the circuit board has an upper surface on which the surface mounting component is to be mounted and a lower surface to be subjected to wave-soldering, the circuit board is composed such that, when the wave-soldering is conducted while joining a terminal of the surface mounting component and the electrode pad of the circuit board by using lead-free solder, the joined site of the terminal of the surface mounting component and the electrode pad of the circuit board is made not to be equal to or higher than a melting temperature of a alloy layer formed at the interface of the terminal or electrode pad and the lead-free solder, the melting temperature of the alloy layer being lower than that of the lead-free solder;
said circuit board is composed such that the temperature of a joined site of a terminal of said surface mounting component and an electrode pad of said circuit board is controlled not to be equal to or more than a melting temperature of a alloy layer formed in said joined site:
and said surface mounting component as claimed in any one of claims 23 to 26,

28. Electronic equipment as claimed in claim 27, wherein:
when said electronic equipment comprises said circuit board, said circuit board is composed such that at least one of a through hole joined to said electrode pad and a land formed around a surrounding of said through hole is made of a material with a thermal conductivity of 100 W/m ∘ K or less.

29. Electronic equipment as claimed in claim 27, wherein:
when said electronic equipment comprises said circuit board, said circuit board is composed such that a through hole to be joined to said electrode pad is filled with a material with a thermal conductivity of 100 W/m ∘ K or less.

30. Electronic equipment as claimed in claim 27, wherein:
when said electronic equipment comprises said circuit board, said circuit board is composed such that at least part of an interconnection for connecting between said through hole and said electrode pad is made of a material with a thermal conductivity of 100 W/m ∘ K or less.

31. Electronic equipment as claimed in claim 27, wherein:
when said electronic equipment comprises said circuit hoard, said circuit board is composed such that at least one of a through hole joined to said electrode pad and a land formed around a surrounding of said through hole is made of nickel or palladium.

32. Electronic equipment as claimed in claim 27, wherein:
when said electronic equipment comprises said circuit board, said circuit board is composed such that a through hole to be joined to said electrode pad is filled with nickel or palladium.

33. Electronic equipment as claimed in claim 27, wherein:
when said electronic equipment comprises said circuit board, said circuit board is composed such that at least part of an interconnection for connecting between a through hole to be joined to said electrode pad and said electrode pad is made of nickel or palladium.

34. Electronic equipment as claimed in claim 27, wherein:
when said electronic equipment comprises said circuit board, said circuit board is composed such that an interconnection for connecting between a through hole to be joined to said electrode pad and said electrode pad has a length of 10 mm. or longer.

35. Electronic equipment as claimed in claim 27, wherein:
when said electronic equipment comprises said circuit board, said circuit board is composed such that at least part of an interconnection for connecting between a through hole to be joined to said electrode pad and said electrode pad has a sectional area of 0.0035 m² or less.

36. A method of mounting a surface mounting component, comprising the steps of mounting said surface mounting component on a circuit board, then wave-soldering on a surface of said circuit board opposite to the mounting surface where said surface mounting component is mounted, wherein:
during said wave-soldering step, at least a vicinity of a joined site of said surface mounting component and said circuit board is cooled, so that temperature of said joined site is kept at a melting temperature or less of a alloy layer foamed in said joined site

37. A method of mounting a surface mounting component, comprising the steps of mounting said surface mounting component on a circuit board, then wave-soldering on a surface of said circuit board opposite to the mounting surface where said surface mounting component is mounted, wherein:
during said wave-soldering step, a heat sink member is disposed on at least the upper surface of said surface mounting component, so that temperature of said joined site of said surface mounting component and said circuit board is kept at a melting temperature or less of a alloy layer formed in said joined site.

38. A method as claimed in claim 37, wherein:
said heat sink member is in contact with a terminal of said surface mounting component or solder in said joined site.

39. A method of mounting a surface mounting component, comprising
the steps of mounting said surface mounting component on a circuit board, then wave-soldering on a surface of said circuit board opposite to the mounting surface where said surface mounting component is mounted, wherein:
during said wave-soldering step, at least a vicinity of a joined site of said surface mounting component and said circuit board is heated, so that whole solder in said joined site is melted.

40. A method of mounting a surface mounting component, comprising the steps of mounting said surface mounting component on a circuit board, then wave-soldering on a surface of said circuit board opposite to the mounting surface where said surface mounting component is mounted, wherein:
during said wave-soldering step, a material for suppressing heat transfer is disposed on a region of the back of said circuit board, said region being located just below at least one of a through hole, a land, and an interconnection, which are to be connected with said surface mounting component, and said surface mounting component.

41. A method as claimed in claim 40, wherein:
said material for suppressing heat transfer is a heat-insulating tape or resin.
